(19) United States
(12) Patent Application Publication
(10) Pub. No.: US 2026/0324373 A1
(43) Pub. Date: Oct. 15, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: FENG-CHING CHU, PINGTUNG COUNTY (TW); FENG-CHENG YANG, HSINCHU COUNTY (TW); CHIEN TA HUANG, HSINCHU (TW); CHIH-HSUAN CHENG, HSINCHU (TW)

(21) Appl. No.: 19/174,963

(22) Filed: Apr. 10, 2025

(51) Int. Cl. H01L 21/762; H01L 21/768; H10D 30/01; H10D 62/17; H10D 64/27; H10D 84/83

(52) U.S. Cl. CPC H10W 10/014; H10D 30/021; H10D 62/235; H10D 64/513; H10D 64/514; H10D 84/83; H10W 10/17; H10W 20/056; H10W 20/062

(57) ABSTRACT

A semiconductor structure includes a plurality of transistor array regions arranged in parallel along a first direction. Each of the plurality of transistor array regions includes a plurality of transistor units arranged separately along a second direction perpendicular to the first direction and separated by a separation structure. Each of the plurality of transistor units includes a central portion, a channel layer, a gate dielectric layer and a gate electrode layer. The central portion includes a first conductive region and a second conductive region separated by a central isolation structure. The channel layer surrounds the central portion. The gate dielectric layer surrounds the channel layer. The gate electrode layer surrounds the gate dielectric layer.

### BACKGROUND

Semiconductor Integrated Circuits (ICs) have undergone exponential growth. Technological advances in integrated circuit materials and design have resulted in generations of integrated circuits, each with smaller and more complex circuits than the previous generation. As the geometries (i.e., the smallest components (or lines) that can be produced using a manufacturing process) shrink during the evolution of integrated circuits, the functional density (i.e., the number of interconnects per chip area) typically increases. This scaling process generally provides benefits by increasing production efficiency and reducing associated costs. Such scaling also increases the complexity of processing and fabrication, and similar developments in integrated circuit processing and fabrication are required to achieve these advances.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a fragmentary cross-sectional view of a semiconductor structure, in accordance with some embodiments of the present disclosure.

FIG. 2 illustrates a fragmentary cross-sectional view of a semiconductor structure, in accordance with some another embodiments of the present disclosure.

FIG. 3 illustrates a perspective partial view of a vertical transistor region of a semiconductor structure, in accordance with some another embodiments of the present disclosure.

FIG. 4A illustrates a top view of the vertical transistor region shown in FIG. 3, in accordance with some embodiments of the present disclosure.

FIG. 4B illustrated a top view of a transistor unit of the vertical transistor region shown in FIG. 3, in accordance with some embodiments of the present disclosure.

FIG. 5 illustrates a perspective partial view of a vertical transistor region of a semiconductor structure, in accordance with some another embodiments of the present disclosure.

FIG. 6 illustrates a top view of the vertical transistor region shown in FIG. 5, in accordance with some embodiments of the present disclosure.

FIG. 7 is a flowchart of a method for forming a semiconductor structure in accordance with some embodiments.

FIGS. 8A to 8I illustrate various perspective views of forming the semiconductor structure in accordance with some embodiments as described in FIG. 7.

FIGS. 9A to 9I illustrate various top views of forming the semiconductor structure as shown in FIGS. 8A to 8I.

FIGS. 10A to 10I illustrate various perspective views of forming the semiconductor structure in accordance with some another embodiments as described in FIG. 7.

FIGS. 11A to 11I illustrate various top views of forming the semiconductor structure as shown in FIGS. 10A to 10I.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Peripheral devices such as power gate or input/output (I/O) devices may be moved from front-end-of-line (FEOL) levels to higher interconnect levels, such as those in back-end-of-line (BEOL) levels, as possible paths for scaling. The power gate is used to turn off a logic transistor block in the standby state to reduce static power consumption. The power gate may be a transistor disposed in the front stage. The I/O device serves as an interface between a computing element (e.g., a central processing unit (CPU)) and an external circuit (e.g., a hard disk). Although about 5% to about 10% of the area may be saved due to such change, fabricating peripheral devices in the BEOL level may compromise carrier (e.g., electron) mobility. Therefore, there is a need to provide a semiconductor including peripheral devices in the BEOL level with improved carrier mobility.

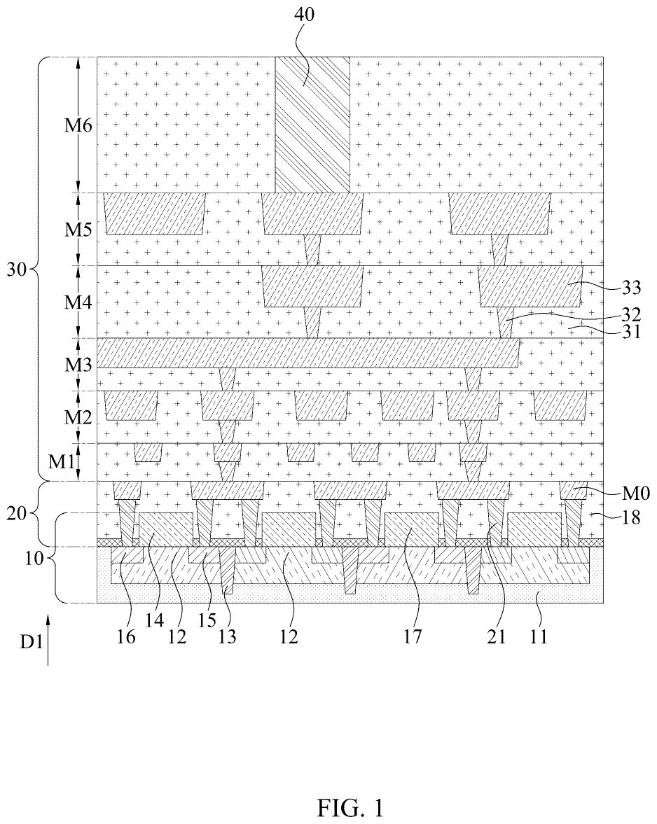

FIG. 1 is a fragmentary cross-sectional view of a semiconductor structure. An IC manufacturing process flow can typically be divided into the three categories, including front-end-of-line (FEOL), middle-end-of-line (MEOL) and back-end-of-line (BEOL) processes. In some embodiments, devices formed by the FEOL processes can be referred to as a FEOL structure 10, the connecting structures formed by the MEOL processes can be referred to as a MEOL connecting structure 20, and the multilayer interconnect (MLI) structures formed by the BEOL processes can be referred to as a BEOL interconnect structure 30. Accordingly, a semiconductor structure can include the FEOL structure 10, the MEOL connecting structure 20 and the BEOL interconnect structure 30. FEOL generally encompasses processes related to fabrication of IC devices, such as transistors. For example, FEOL processes can include forming isolation structures for isolating IC devices, gate structures, and source and drain structures (also referred to as source/drain structures) and that form a transistor. MEOL generally encompasses processes related to fabrication of connecting structures (also referred to as contacts or plugs) that connect to conductive features (or conductive regions) of the IC devices. For example, MEOL processes can include forming connecting structures that connect to the gate structures and connecting structures that connect to the source/drain structures. BEOL generally encompasses processes related to fabrication of MLI structures that electrically connect the IC devices and the connecting structures fabricated by FEOL and MEOL processes.

As shown in FIG. 1, the FEOL structure 10 comprises a substrate 11, a plurality of channel regions 12 in/over the substrate 11, a plurality of isolation features 13, a plurality of gate structures 14, a plurality of source/drain features 15/16, an etch stop layer 17 and an interlayer dielectric (ILD) layer 18. The isolation features 13 are disposed over the substrate 11 and between the plurality of channel regions 12. The isolation features 13 comprise dielectric materials with a dielectric constant between about 3 and about 5. For example, dielectric materials may be oxide-based materials. In some embodiments, a top surface of each of the isolation features may be non-planar. The gate structures 14 are disposed over the plurality of channel regions 12. Each of the gate structures 14 comprises a gate dielectric layer and at least one metal/semiconductor layer over the gate dielectric layer. The gate dielectric layer and the isolation feature 13 intermix at an interface between the gate dielectric layer and the isolation feature 13. Each of the source/drain features 15/16 interfaces a sidewall of one of the channel regions 12. The etch stop layer 17 continuously extends over the plurality of source/drain features 15/16. The ILD layer 18 is disposed over the etch stop layer 17. Top surfaces of the isolation features 13 are spaced apart from the ILD layer 18 by the etch stop layer 17.

The MEOL connecting structure 20 comprises a plurality of connecting structures 21 (also referred to as contacts or plugs) disposed in the ILD layer 18 and a plurality of conductive pads M0 electrically couple to source/drain features 15/16 and/or the gate structure 14. In some embodiments, the MEOL connecting structure 20 (i.e., the connecting structures 21) electrically connect the FEOL structures 10 to the BEOL interconnect structures 30.

The BEOL interconnect structure 30 is disposed on the MEOL connecting structure 20. In some embodiments, the interconnect structure 30 includes a zeroth metallization layer M0, a first metallization layer M1, a second metallization layer M2, a third metallization layer M3, a fourth metallization layer M4, a fifth metallization layer M5, a sixth metallization layer M6, and one or more further metallization layers Mn stacking along a first direction D1. Each metallization layer (M1, M2 . . . Mn) comprises a dielectric layer 31 (e.g., inter-metal dielectrics (IMDs), passivation layers or the like), a plurality of vias 32 and a plurality of conductive patterns 33. The dielectric layer 31 may be formed of oxides such as un-doped silicate glass (USG), fluorinated silicate glass (FSG), low-k dielectric materials, or the like. The low-k dielectric materials may have k values lower than 3.8, although the dielectric materials of IMDs may also be close to 3.8. In some embodiments, the k values of the low-k dielectric materials are lower than about 3.0, and may be lower than about 2.5. The vias 32 passes through the dielectric layer 31. The conductive patterns 33 are embedded in the dielectric layer 31. In some embodiments, the conductive patterns 33 located at different metallization layer may be connected to each other through the vias 32. The vias 32 may be formed by a variety of techniques, e.g., electroplating, electroless plating, high-density ionized metal plasma (IMP) deposition, high-density inductively coupled plasma (ICP) deposition, sputtering, physical vapor deposition (PVD), chemical vapor deposition (CVD), low-pressure chemical vapor deposition (LPCVD), plasma-enhanced chemical vapor deposition (PECVD), and the like. The conductive patterns 33 of the zeroth metallization layer M0 are electrically connected to the connect structures 21 disposed in the MEOL connecting structure 20 and thus can be further electrically connected to devices in the FEOL structure 10.

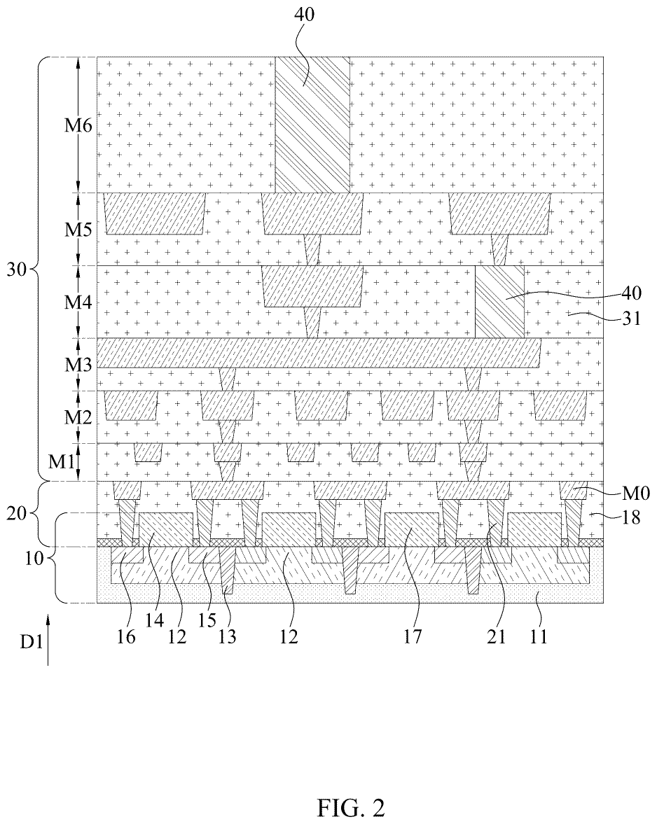

The BEOL interconnect structure 30 may further comprise one or more vertical transistor regions 40. Each vertical transistor region 40 is disposed in one of the metallization layers (M1, M2 . . . Mn). As shown in FIG. 1, the BEOL interconnect structure 30 comprises a vertical transistor region 40 in the sixth metallization layer M6, which may be connected to the conductive pattern 33 in the fifth metallization layer M5 through a via 32 and may be connected to a conductive pattern 33 in a further metallization layer Mn according to required design. As shown in FIG. 2, the BEOL interconnect structure 30 comprises a plurality of vertical transistor regions 40 formed in different metallization layers (i.e., the fourth metallization layer M4 and the sixth metallization layer M6 as illustrated in FIG. 2).

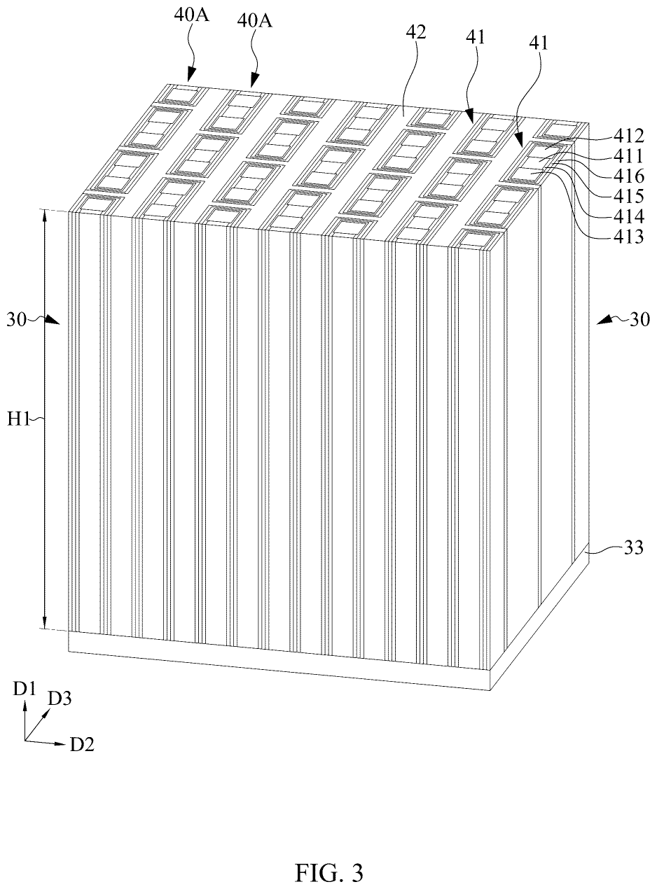

The vertical transistor region 40 is formed in the dielectric layer 31 of one of the metallization layers (M1, M2 . . . Mn) and may be an I/O transistor or a power gate transistor. The vertical transistor region 40 comprises a plurality of transistor array regions 40A (shown in FIG. 3) arranged in parallel along a second direction D2, perpendicular to the first direction D1.

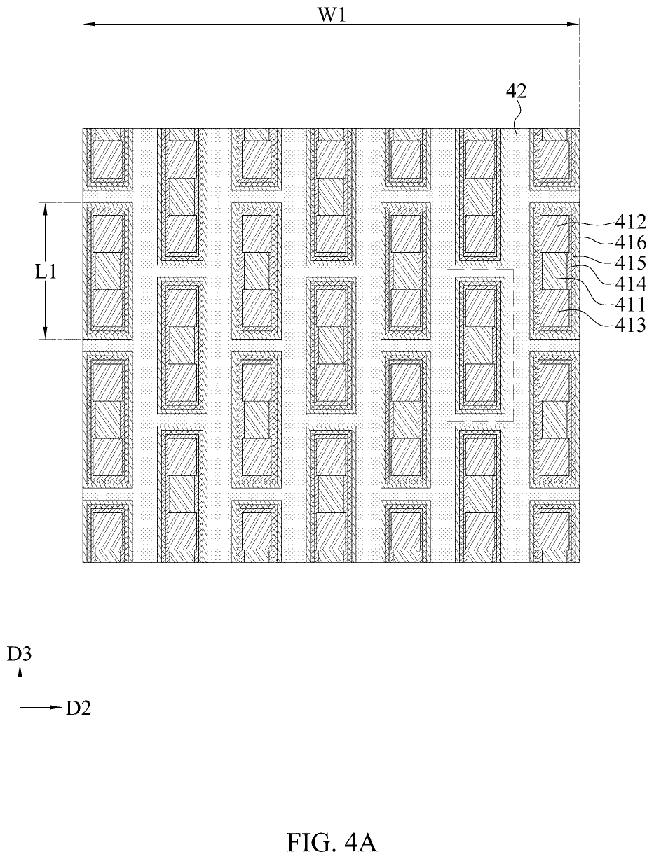

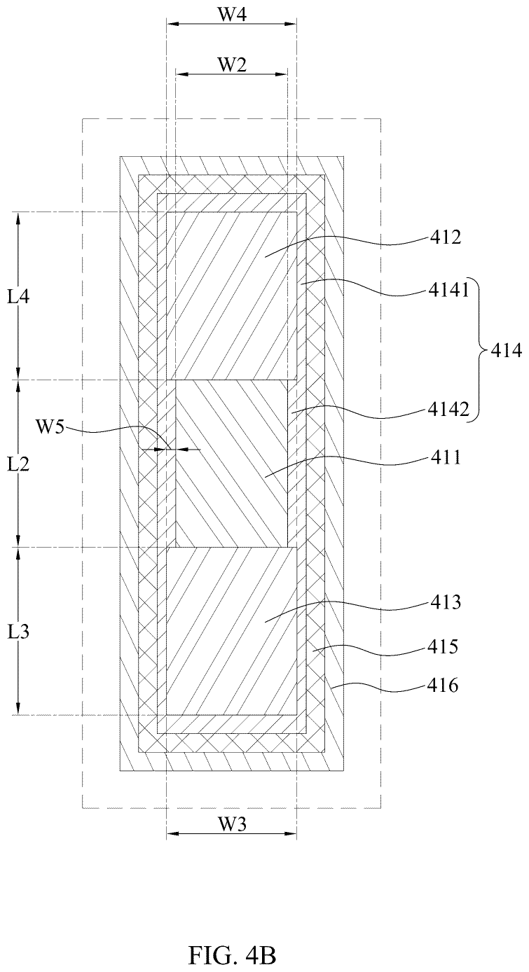

Further referring to FIGS. 3, 4A and 4B, each transistor array region 40A comprises a plurality of transistor units 41 arranged separately along a third direction D3, perpendicular to the first direction D1 and also perpendicular to the second direction D2. The plurality of transistor units 41 are separated from each other by a separation structure 42. The number of the transistor units 41 in one vertical transistor region 40 can be adjusted according to required design. Each of the transistor units 41 has a rectangular or circular top cross-section. In some embodiments, each vertical transistor region 40 may comprise about 10 to about 200 transistor units 41. In some embodiments, each vertical transistor region 40 may comprise about 50 to about 150 transistor units 41. In some embodiments, each vertical transistor region 40 may comprise about 80 to about 100 transistor units 41. Each of the plurality of transistor units 41 has a height H1 (shown in FIG. 3) along the first direction D1 and a length L1 (shown in FIG. 4A) along the third direction D3. A ratio of the height H1 to the length L1 may range from about 30:1 to about 5:1. In some embodiments, the ratio of the height H1 to the length L1 may range from about 25:1 to about 10:1. In some embodiments, the ratio of the height H1 to the length L1 may range from about 20:1 to about 12:1. Each vertical transistor region 40 has a width W1 along the second direction D2. A ratio of the height H1 to the width W1 may range from about 30:1 to about 2:1. In some embodiments, the ratio of the height H1 to the width W1 may range from about 25:1 to about 5:1. In some embodiments, the ratio of the height H1 to the width W1 may range from about 20:1 to about 10:1. In some embodiments, the width W1 of the vertical transistor region 40 may range from about 300 nm to about 1500 nm. In some embodiments, the width W1 of the vertical transistor region 40 may range from about 400 nm to about 1200 nm. In some embodiments, the width W1 of the vertical transistor region 40 may range from about 500 nm to about 1000 nm. In some embodiments, a pitch between two of the vertical transistor region 40 may range from about 100 nm to about 300 nm. In some embodiments, the pitch between two of the vertical transistor region 40 may range from about 130 nm to about 250 nm. In some embodiments, the pitch between two of the vertical transistor region 40 may range from about 150 nm to about 200 nm. For example, the pitch between two of the vertical transistor region 40 may be about 180 nm.

In some embodiments, the height H1 of the transistor unit 41 may range from about 1,000 nm to about 3,000 nm. In some embodiments, the height H1 of the transistor unit 41 may range from about 1,500 nm to about 2,500 nm. In some embodiments, the height H1 of the transistor unit 41 may range from about 1,800 nm to about 2,200 nm. For example, the height H1 of the transistor unit 41 may be about 2,000 nm. In some embodiments, the length L1 of the transistor unit 41 may range from about 70 nm to about 150 nm. In some embodiments, the length L1 of the transistor unit 41 may range from about 80 nm to about 130 nm. In some embodiments, the length L1 of the transistor unit 41 may range from about 90 nm to about 120 nm. For example, the length L1 of the transistor unit 41 may be about 100 nm.

As shown in FIG. 4A, the plurality of transistor units 41 in one transistor array region 40A and the plurality of transistor units 41 in an adjacent transistor array region 40A are in a XY staggered array configuration (i.e., along the second direction D2 and the third direction D3). Each of the plurality of transistor units 41 comprises a central portion, a channel layer 414, a gate dielectric layer 415 and a gate electrode layer 416. The central portion comprises a central isolation structure 411, a first conductive region 412 and a second conductive region 413.

The central isolation structure 411 comprises dielectric materials or isolation materials, such as oxide-based materials. A height of the central isolation structure 411 is substantially identical to the height H1 of the transistor unit 41. The central isolation structure 411 has a width W2 along the second direction D2 and a length L2 along the third direction D3. The first conductive region 412 and the second conductive region 413 are disposed beside opposite sides of the central isolation structure 411, so that the central isolation structure 411 is sandwiched by the first conductive region 412 and the second conductive region 413 along the third direction D3. The first conductive region 412 and the second conductive region 413 may be referred to as source/drain regions. Source/drain region(s) may refer to a source or a drain, individually or collectively dependent upon the context.

In some embodiments, the first conductive region 412 and the second conductive region 413 comprise tungsten (W), copper (Cu), titanium nitride (TiN), tantalum nitride (TaN), aluminum (Al), ruthenium (Ru), cobalt (Co), indium tin oxide (ITO), doped semiconductor material (e.g., p-doped or n-doped silicon), and/or other metals. The first conductive region 412 and the second conductive region 413 extend in the first direction D1, so that heights of the first conductive region 412 and the second conductive region 413 are also substantially identical to the height H1 of the transistor unit 41. The first conductive region 412 has a length L3 along the third direction D3 and the second conductive region 413 has a length L4 along the third direction D3, which may be substantially identical to the length L3 of the first conductive region 412. In some embodiments, a ratio of the length L3 of the first conductive region 412, the length L4 of the second conductive region 413 to the length L2 of the central isolation structure 411 may range from about 3:3:1 to about 1:1:1. In some embodiments, a ratio of the length L3 of the first conductive region 412, the length L4 of the second conductive region 413 to the length L2 of the central isolation structure 411 may range from about 2:2:1 to about 3:3:2. The first conductive region 412 has a volume, which may be substantially identical to a volume of the second conductive region 413.

The first conductive region 412 has a width W3 along the second direction D2 and the second conductive region 413 has a width W4 along the second direction D2. The width W3 of the first conductive region 412 is substantially identical to the width W4 of the second conductive region 413. In some embodiments, each of the width W3 of the first conductive region 412 and the width W4 of the second conductive region 413 is greater than the width W2 of the central isolation structure 411 so that the central portion has a dumbbell top cross-section. In some embodiments, a ratio of the width W3 of the first conductive region 412, the width W4 of the second conductive region 413 to the width W2 of the central isolation structure 411 may range from about 5:5:3 to about 50:50:49. In some embodiments, a ratio of the width W3 of the first conductive region 412, the width W4 of the second conductive region 413 to the width W2 of the central isolation structure 411 may range from about 10:10:7 to about 10:10:9. When the vertical transistor region 40 is disposed in an Nth metallization layer Mn, the first conductive region 412 can be electrically connected to a conductive pattern 33 in an overlying Mn+1 metallization layer and the second conductive region 413 can also be electrically connected to another conductive pattern 33 in the Mn+1 metallization layer.

The channel layer 414 surrounds the central portion and thus serves as a sidewall of the central portion. The channel layer 414 may be an N-type channel or a P-type channel. When the channel layer 414 is an N-type channel, the channel layer 414 may comprise indium gallium zinc oxide (IGZO), ZnO, In₂O₃, SnO₂, and so on. When the channel layer 414 is a P-type channel, the channel layer 414 may comprise NiO, Cu₂O, CuAlO₂, CuGaO₂, CuInO₂, SrCu₂O₂, SnO, and so on. The channel layer 414 in the vertical transistor region 40 disposed in the BEOL interconnect structure 30 is usually a P-type channel, but it can also be an N-type channel according to required design. The channel layer 414 extends in the first direction D1, so that height of the channel layer 414 is substantially identical to the height H1 of the transistor unit 41 and may be also substantially identical to the heights of the first conductive region 412 and the second conductive region 413. As illustrated in FIG. 4B, due to the dumbbell top cross-section of the central portion, the channel layer 414 has a channel ring 4141 and two extending portions 4142. The channel ring 4141 abuts sidewalls of the first conductive region 412 and the second conductive region 413, and is separated from the central isolation structure 411 by the extending portions 4142. The channel ring 4141 has a thickness, which may range from about 1 nm to about 7 nm. In some embodiments, the thickness of the channel ring 4141 may range from about 2 nm to about 6 nm. In some embodiments, the thickness of the channel ring 4141 may range from about 3 nm to about 5 nm. A sum of a width W5 of the extending portions 4142 and the width W2 of the central isolation structure 411 substantially equals to the width W3 of the first conductive region 412 and substantially equals to the width W4 of the second conductive region 413. In some embodiments, the width W5 of the extending portions 4142 may range from about 0.1 nm to about 2.5 nm. In some embodiments, the width W5 of the extending portions 4142 may range from about 0.5 nm to about 2 nm. In some embodiments, the width W5 of the extending portions 4142 may range from about 1 nm to about 1.5 nm. In some embodiments, the channel layer 414 may be formed using atomic layer deposition (ALD) or other suitable deposition methods.

The gate dielectric layer 415 surrounds the channel layer 414 so that the channel layer 414 is sandwiched by the gate dielectric layer 415 and the central portion of the transistor unit 41. The gate dielectric layer 415 extends in the first direction D1, so that a height of the gate dielectric layer 415 is substantially identical to the height H1 of the transistor unit 41 and may be also substantially identical to the heights of the first conductive region 412, the second conductive region 413 and the channel layer 414. The gate dielectric layer 415 may be formed of a high-k dielectric material, such as metal oxides, including but not limited to hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), SiO₂, Al2O₃, metal nitrides, metal silicates, transition metal-oxides, transition metal-nitrides, transition metal-silicates, oxynitrides of metals, metal aluminates, zirconium silicate, zirconium aluminate, zirconium oxide, titanium oxide, aluminum oxide, hafnium dioxide-alumina (HfO₂—Al₂O₃) alloy, other suitable high-k dielectric materials, or combinations thereof. Alternatively, the gate dielectric layer 415 may include silicon nitride, silicon oxynitride or silicon oxide. In some embodiments, the gate dielectric layer 415 may be formed using ALD or other suitable deposition methods. The gate dielectric layer 415 has a thickness, which may range from about 1 nm to about 7 nm. In some embodiments, the thickness of the gate dielectric layer 415 may range from about 2 nm to about 6 nm. In some embodiments, the thickness of the gate dielectric layer 415 may range from about 3 nm to about 5 nm. In some embodiments, the gate dielectric layer 415 may comprise HfO₂, SiO₂, Al₂O₃, SiON, and so on.

The gate electrode layer 416 surrounds the gate dielectric layer 415 so that the gate dielectric layer 415 is sandwiched by the gate electrode layer 416 and the channel layer 414. The gate dielectric layer 415 extends in the first direction D1, so that a height of the gate dielectric layer 415 is substantially identical to the height H1 of the transistor unit 41 and may be also substantially identical to the heights of the first conductive region 412, the second conductive region 413, the channel layer 414 and the gate dielectric layer 415. The gate electrode layer 416 can be electrically connected to a conductive pattern 33 in an underlying Mn-1 metallization layer. The gate electrode layer 416 may include a metallic material, polycrystalline silicon, doped silicon, or a metal compound, such as metal nitride. The metallic material may include, for example, but not limited to, tungsten (W), silver (Ag), aluminum (Al), copper, nickel (Ni), other suitable materials, alloys thereof, or combinations thereof. The metal compound may include, for example, but not limited to, titanium nitride (TiN), tantalum nitride (TaN), metal silicide, other suitable materials, or combinations thereof. Other suitable materials for fabricating the gate electrode are within the contemplated scope of the present disclosure. The gate electrode layer 416 has a thickness, which may range from about 2 nm to about 10 nm. In some embodiments, the thickness of the gate electrode layer 416 may range from about 3 nm to about 8 nm. In some embodiments, the thickness of the gate electrode layer 416 may range from about 5 nm to about 7 nm. A top of the gate electrode layer 416 may substantially coplanar with a top of the gate dielectric layer 415, a top of the channel layer 414 and a top of the central portion (including a top of the central isolation structure 411, a top of the first conductive region 412 and a top of the second conductive region 413).

The separation structure 42 is disposed in the dielectric layer 31 of one of the metallization layers (M1, M2 . . . Mn) to separate the transistor units 41 from each other. The separation structure 42 may extend from the dielectric layer 31 and thus has materials substantially identical to the materials for forming the dielectric layer 31. In some embodiments, the separation structure 42 comprises dielectric materials or isolation materials, such as oxide-based materials. In some embodiments, the materials for forming the separation structure 42 are substantially identical to those for forming the central isolation structure 411. A height of the separation structure 42 is substantially identical to the height H1 of the transistor unit 41.

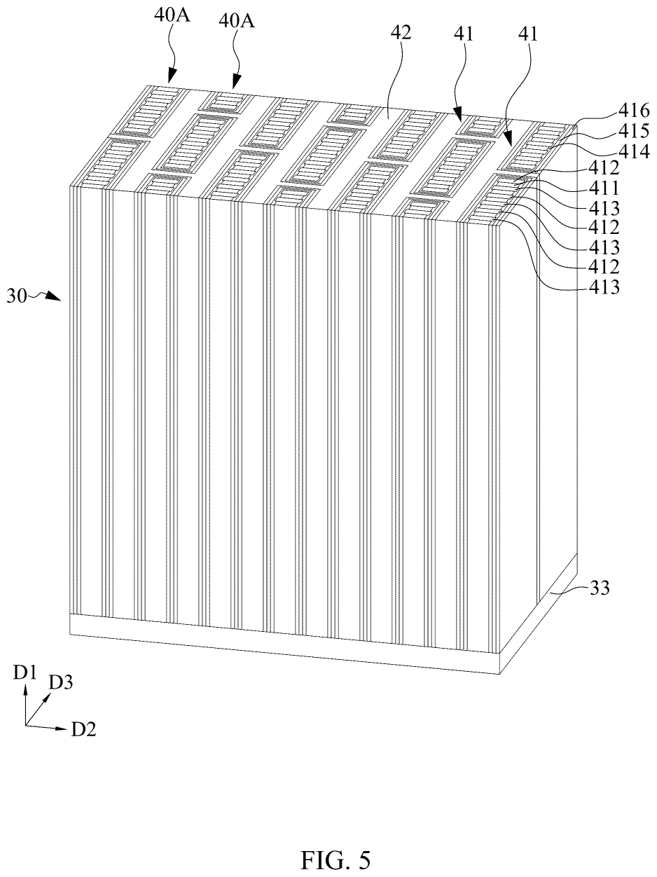

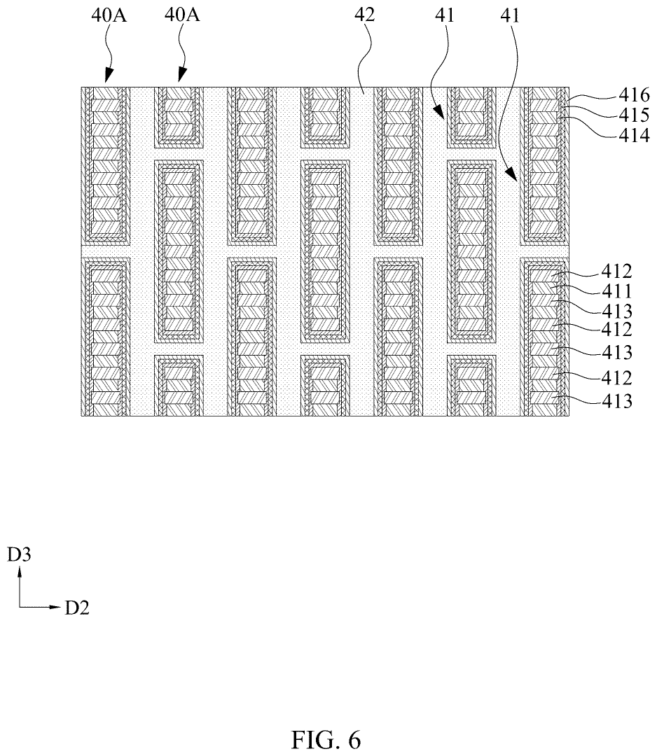

With reference to FIGS. 5 and 6, in some embodiments, each of the plurality of transistor units 41 comprises more than one first conductive region 412 and more than one second conductive region 413, so that the transistor unit 41 can share common source/drain regions. These are, of course, merely examples and are not intended to be limiting.

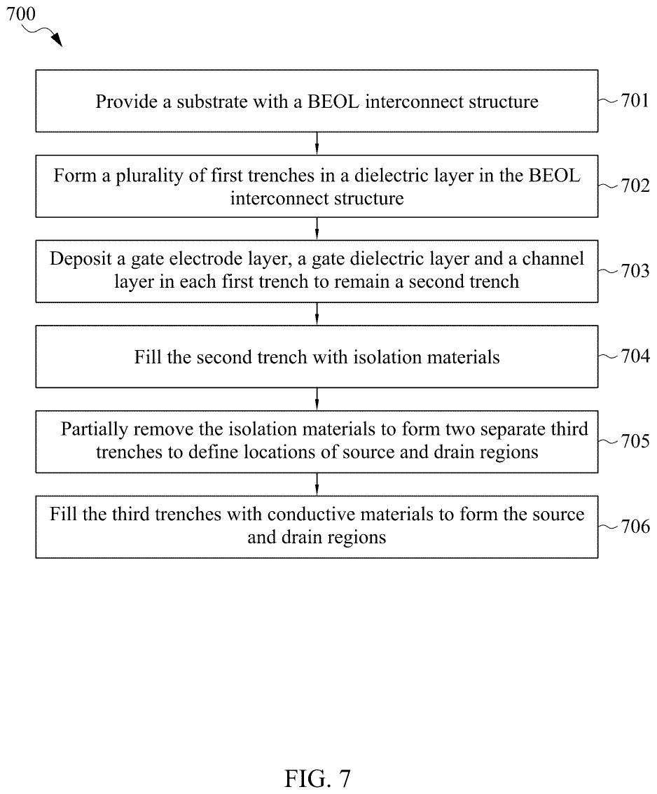

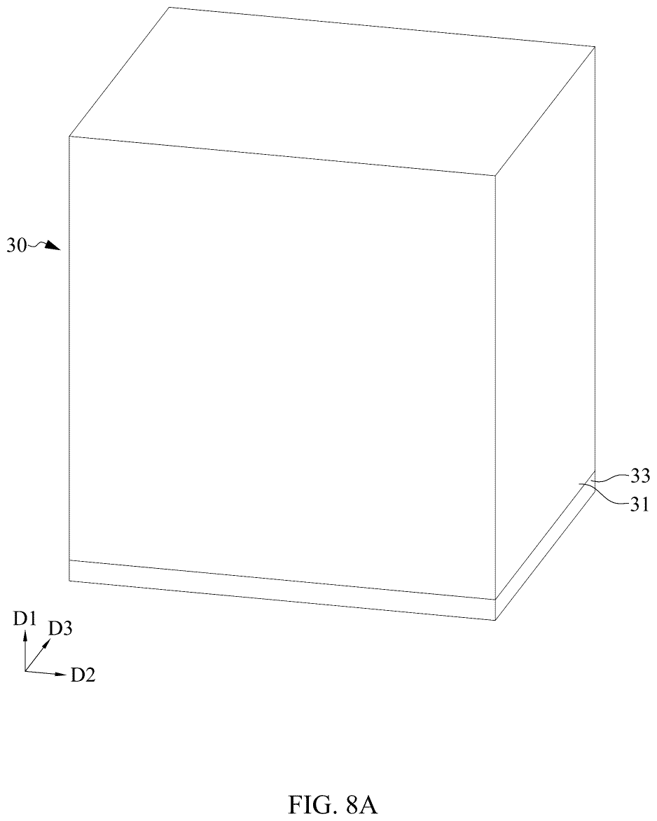

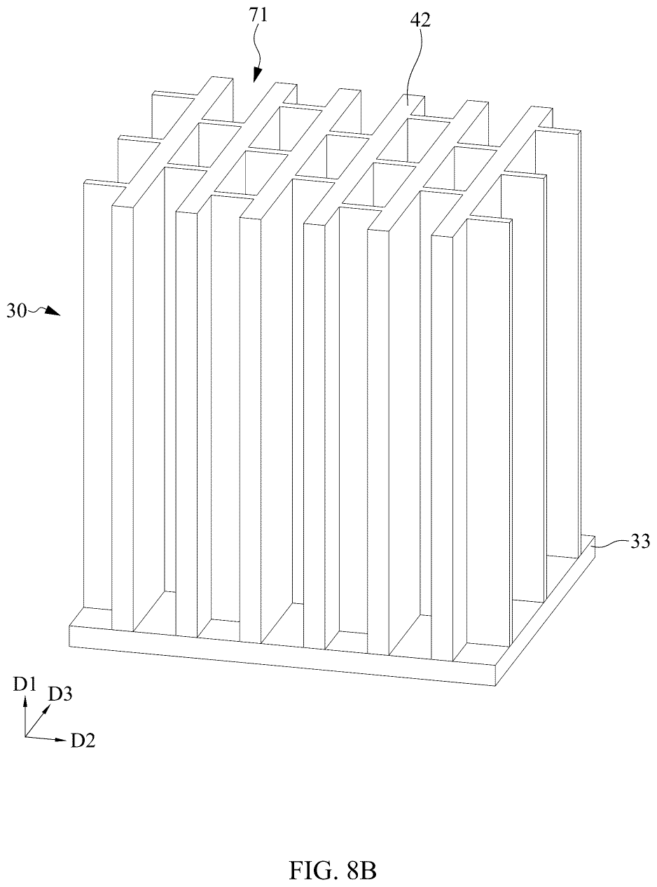

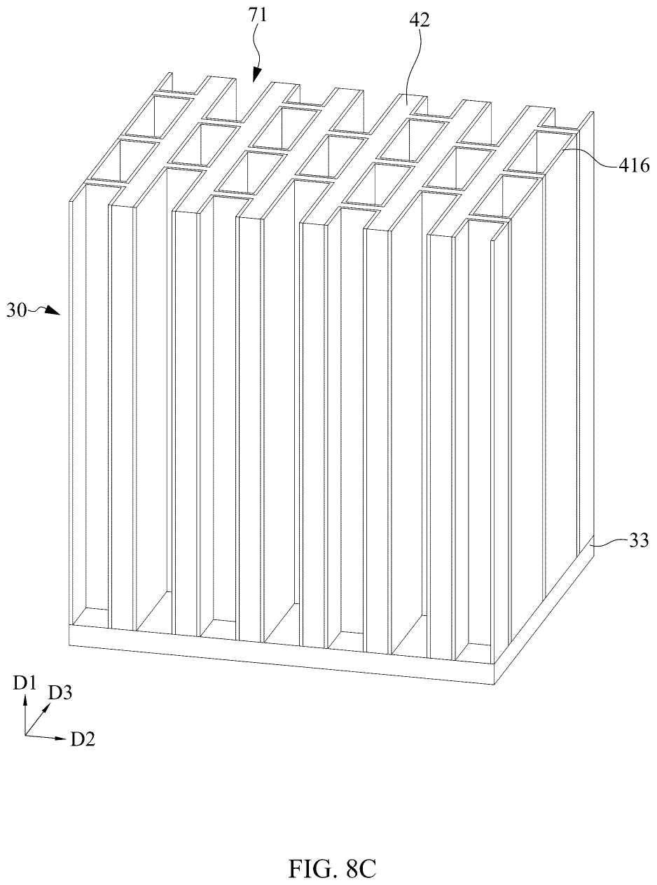

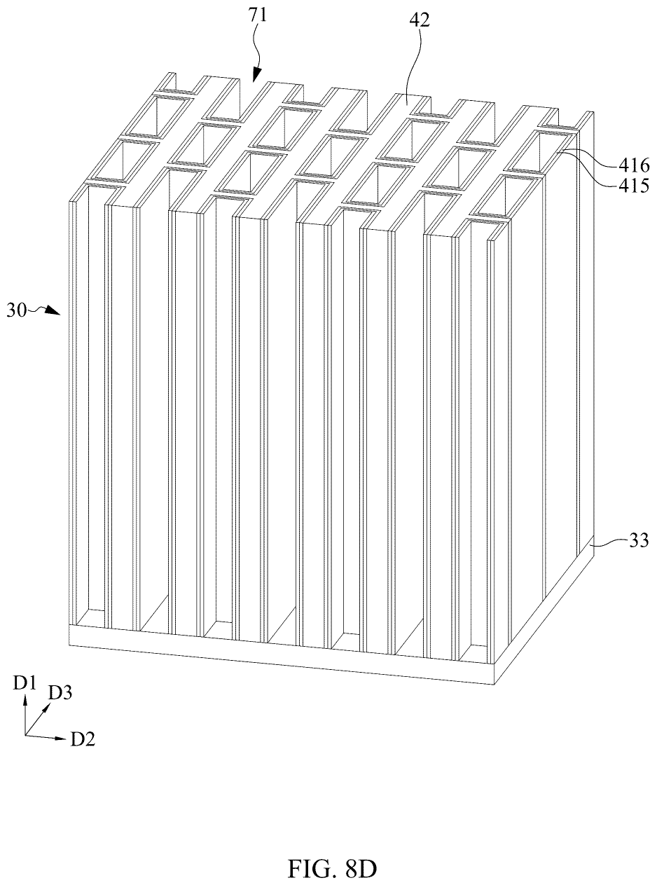

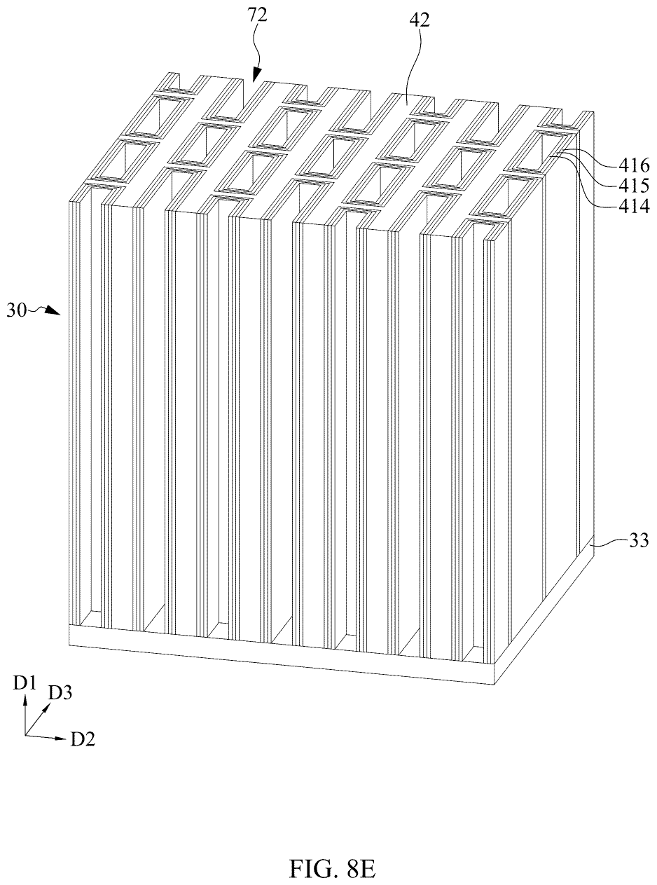

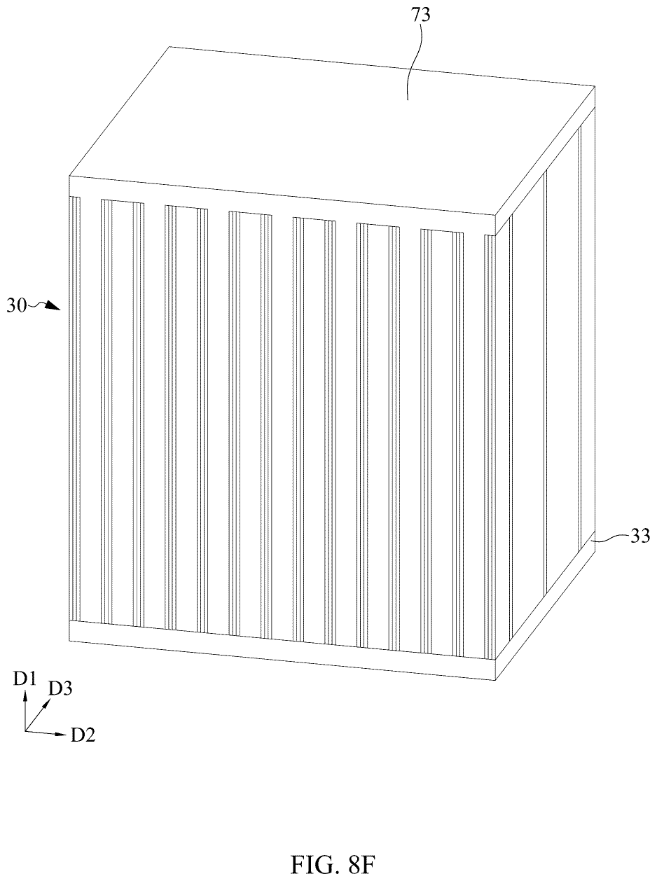

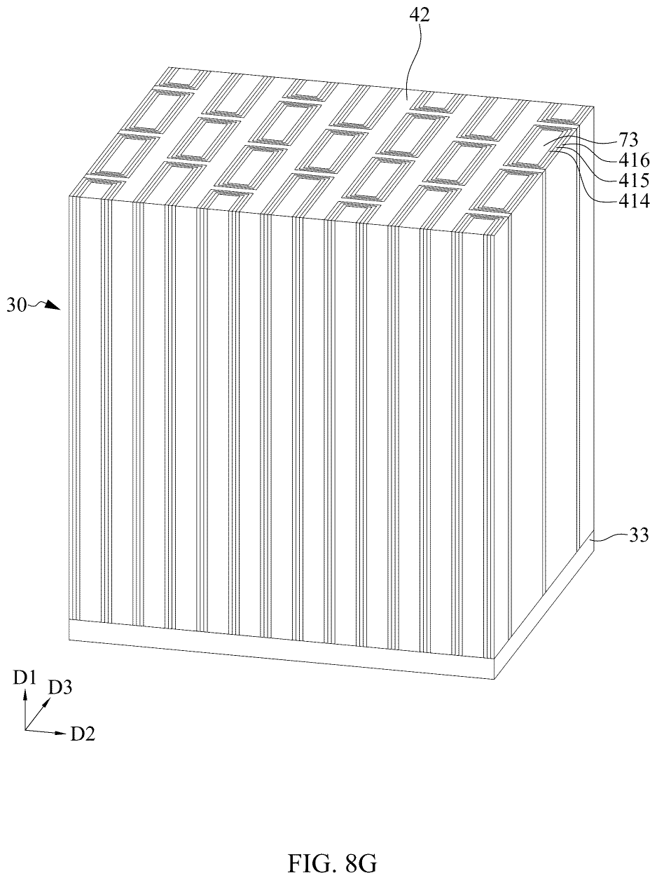

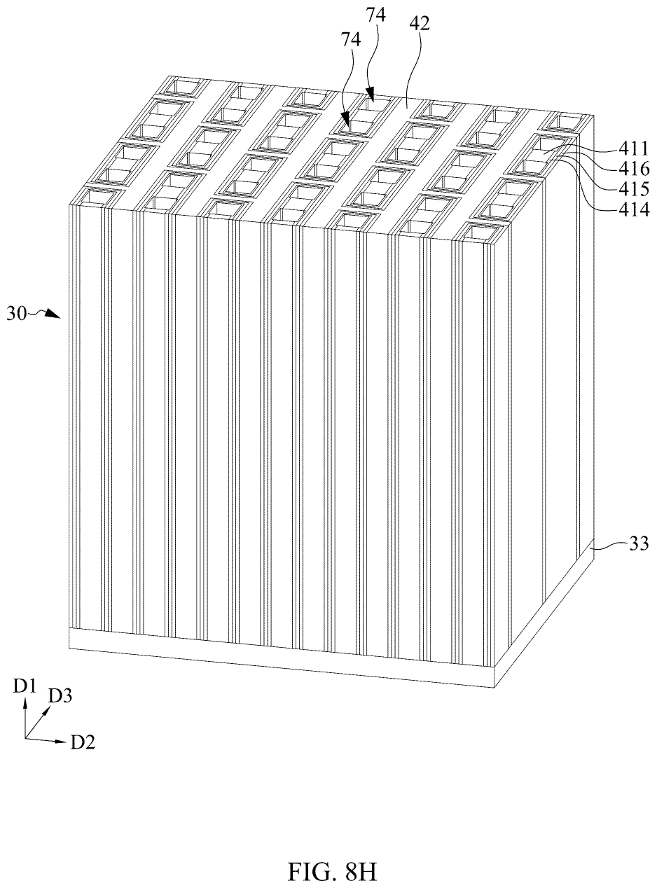

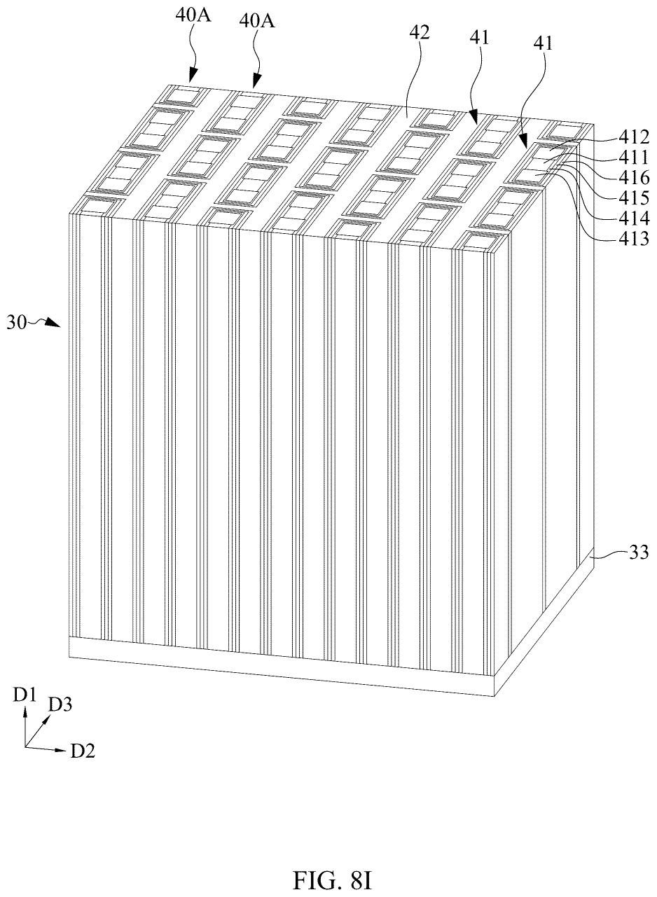

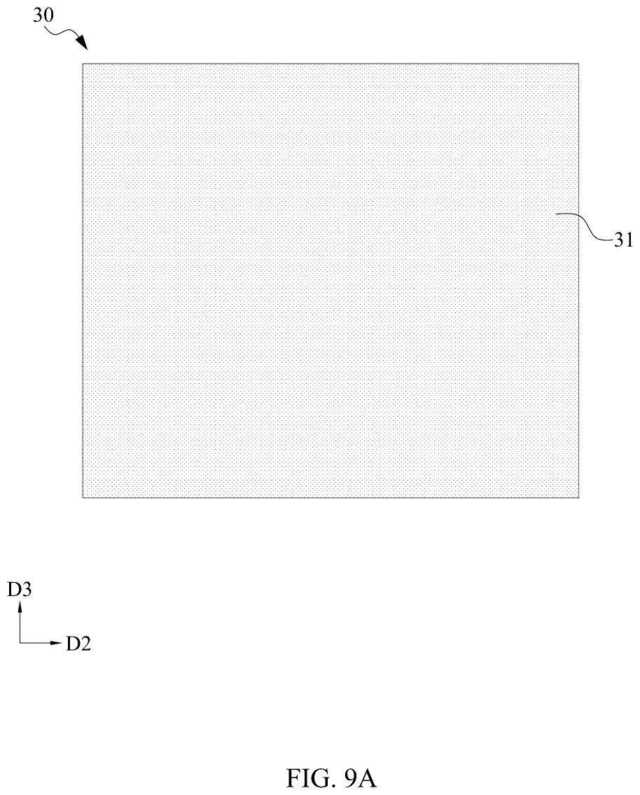

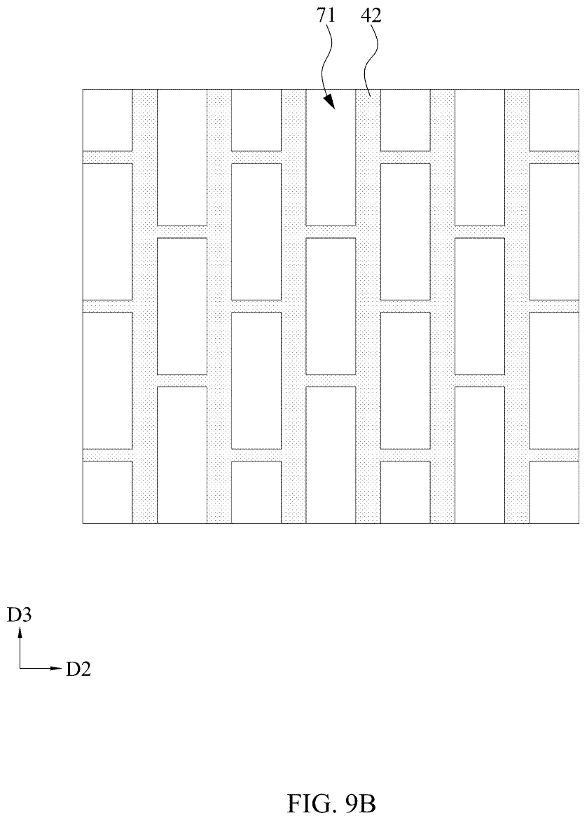

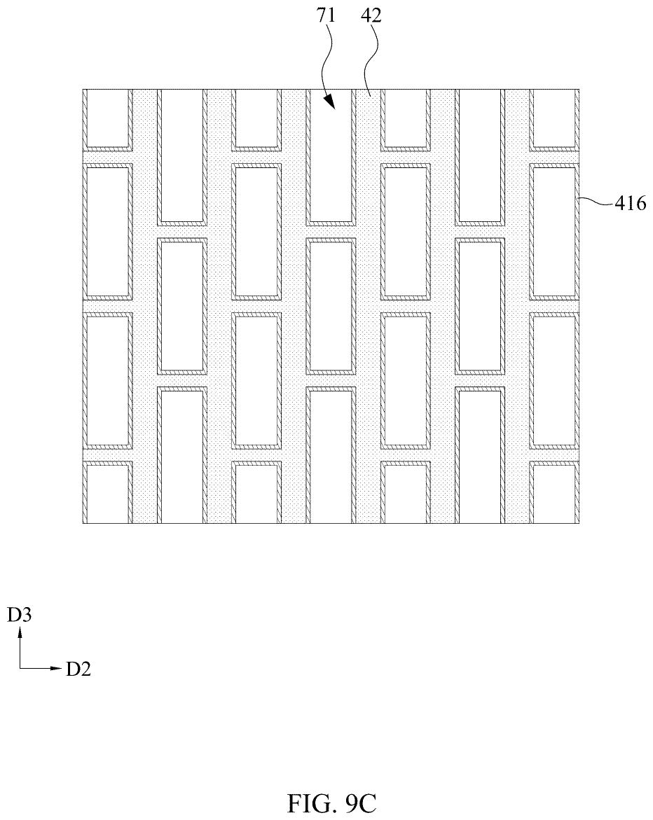

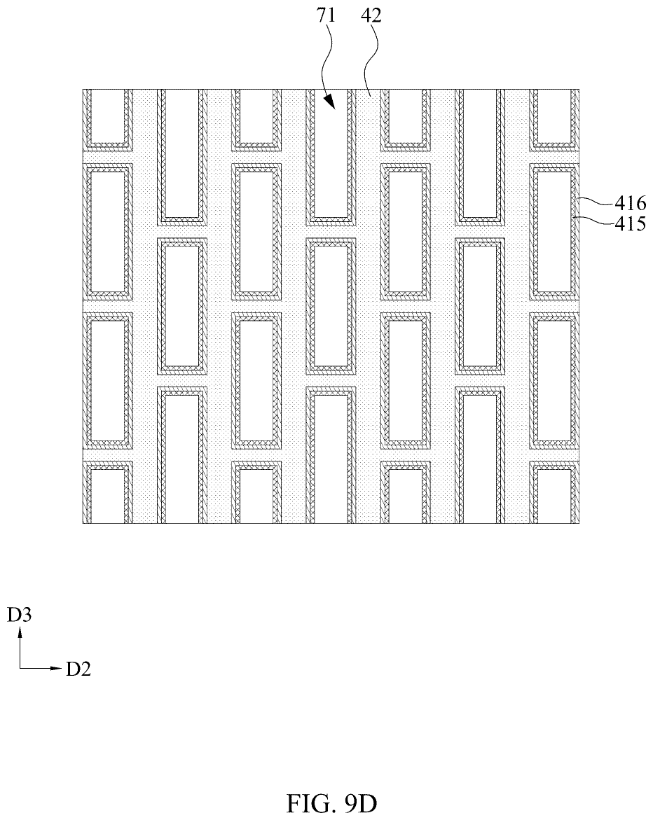

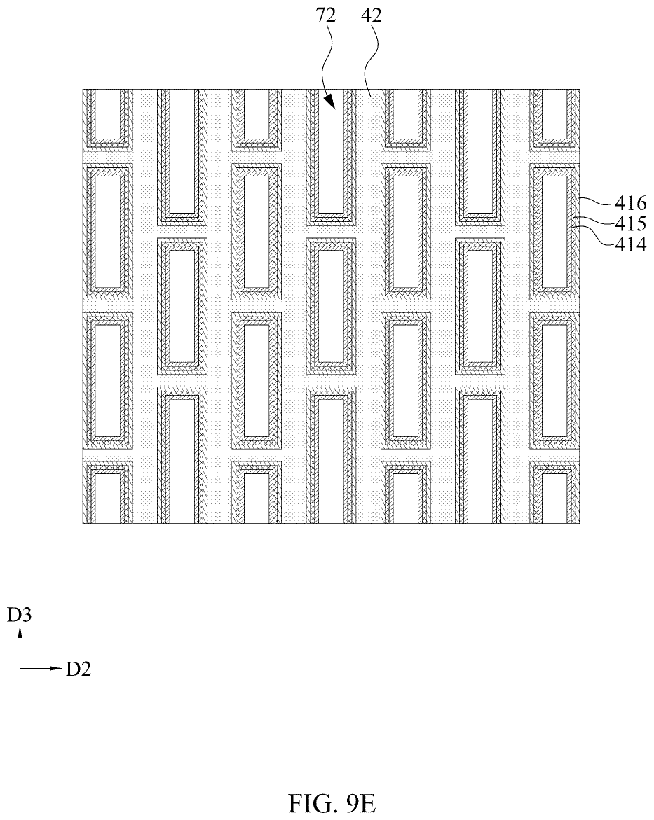

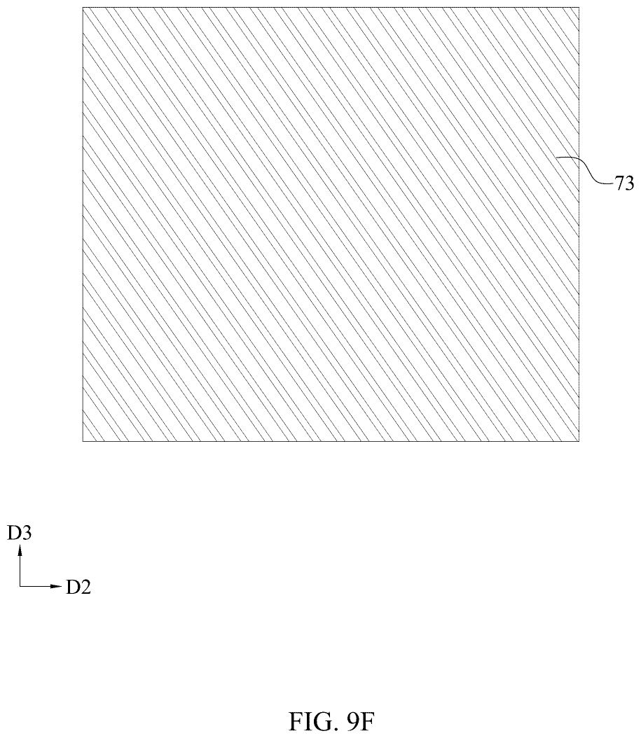

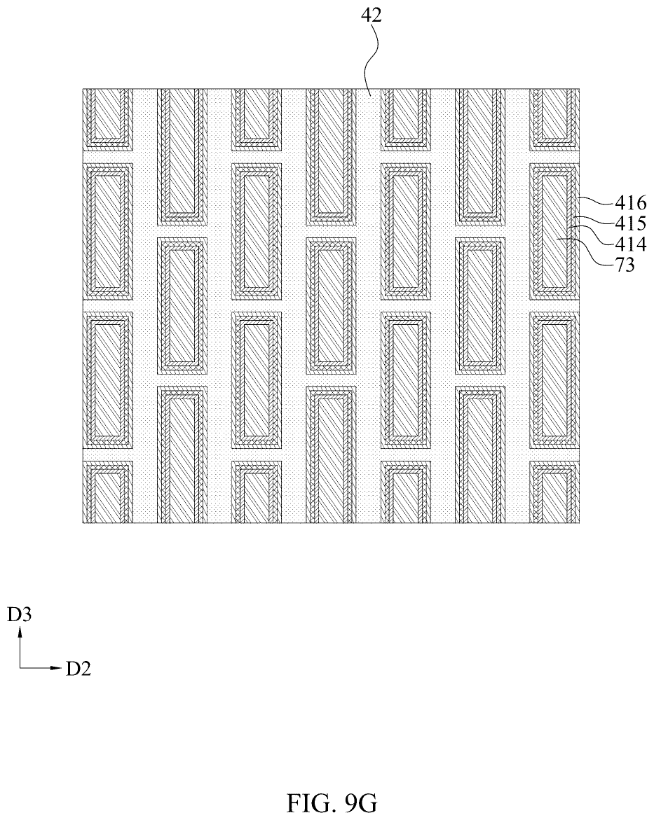

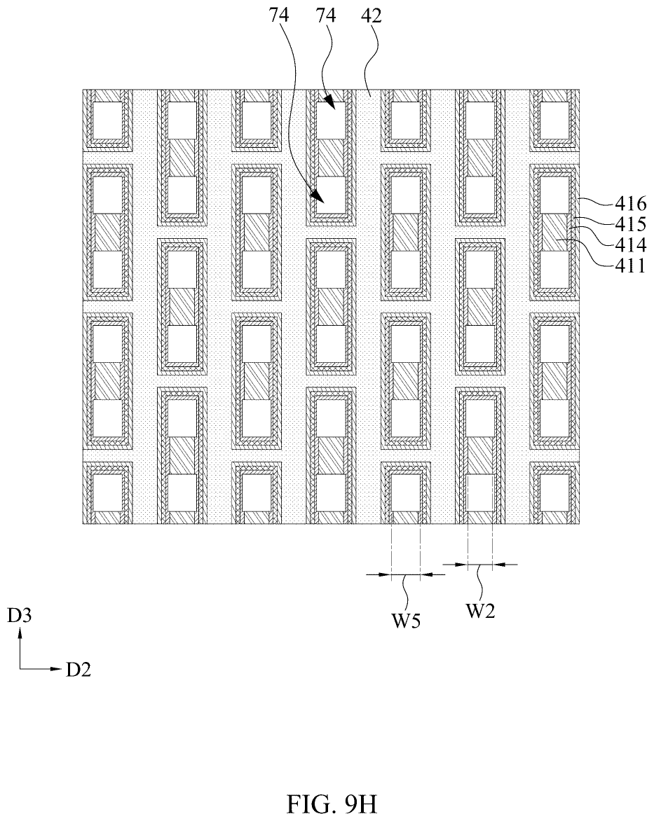

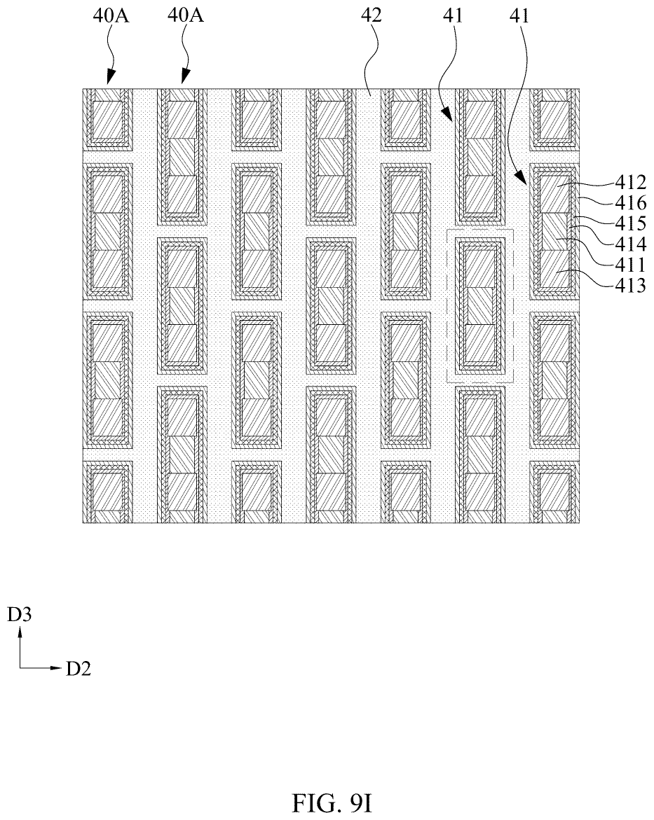

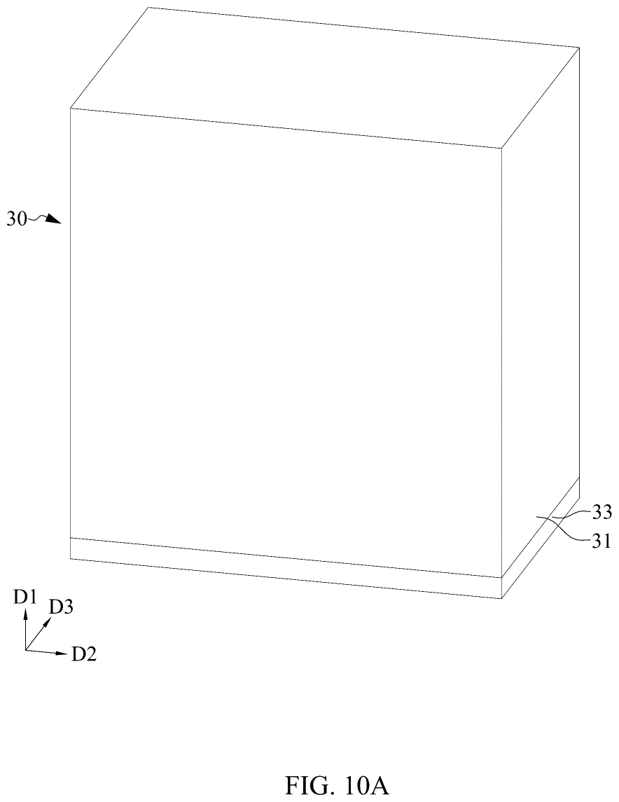

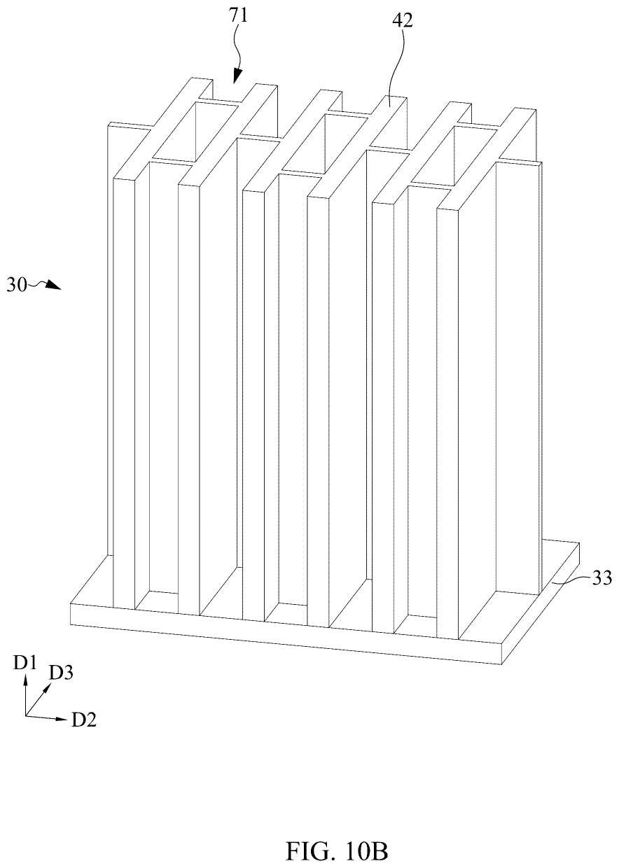

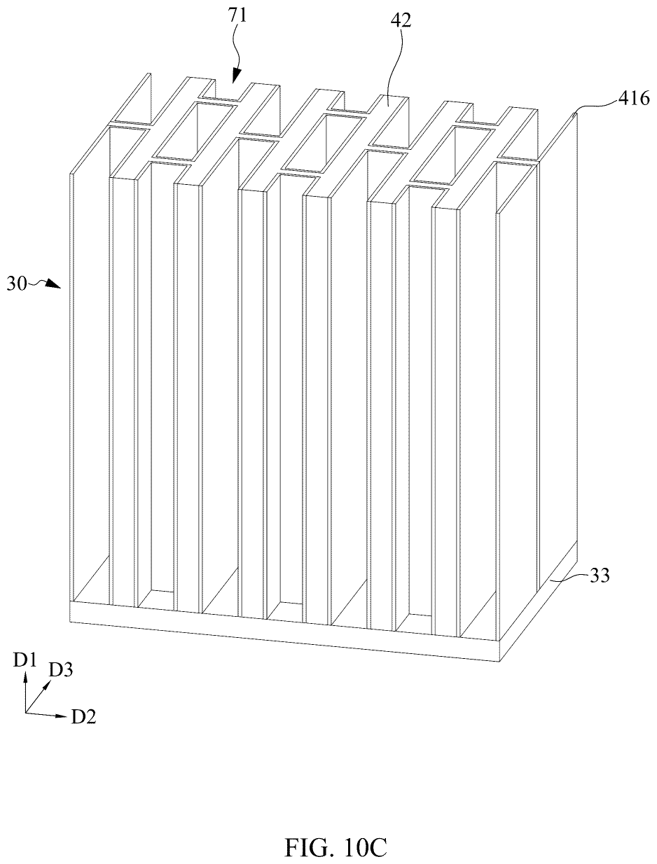

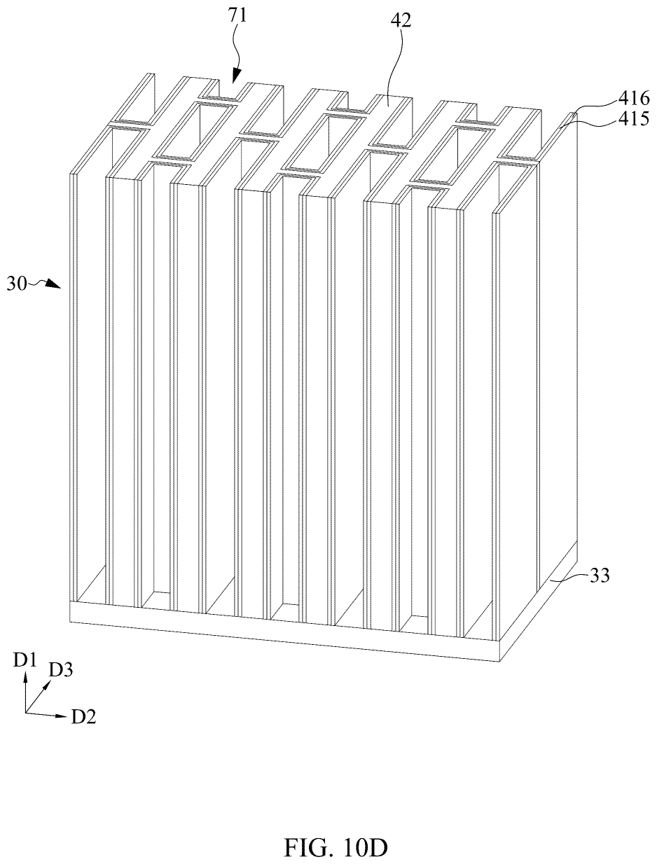

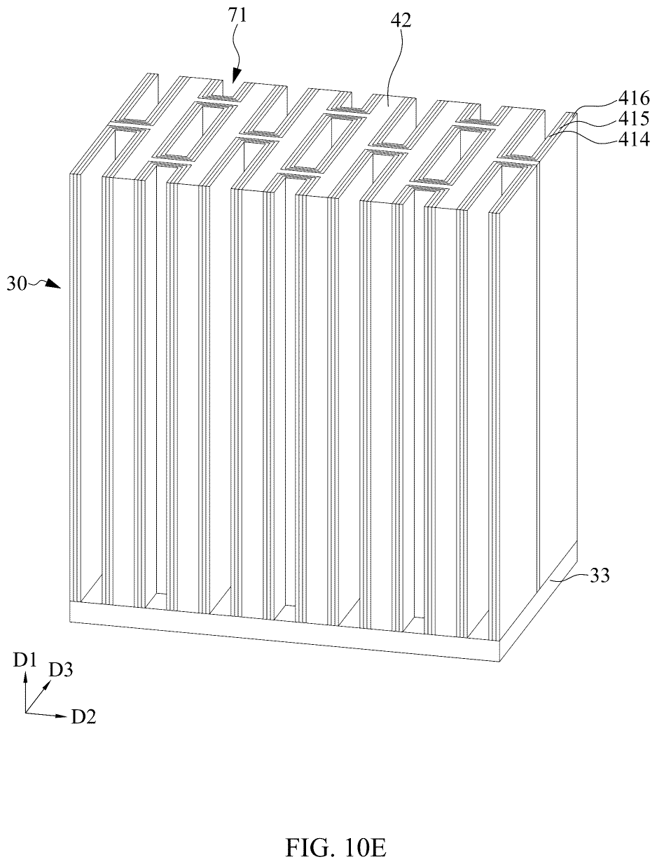

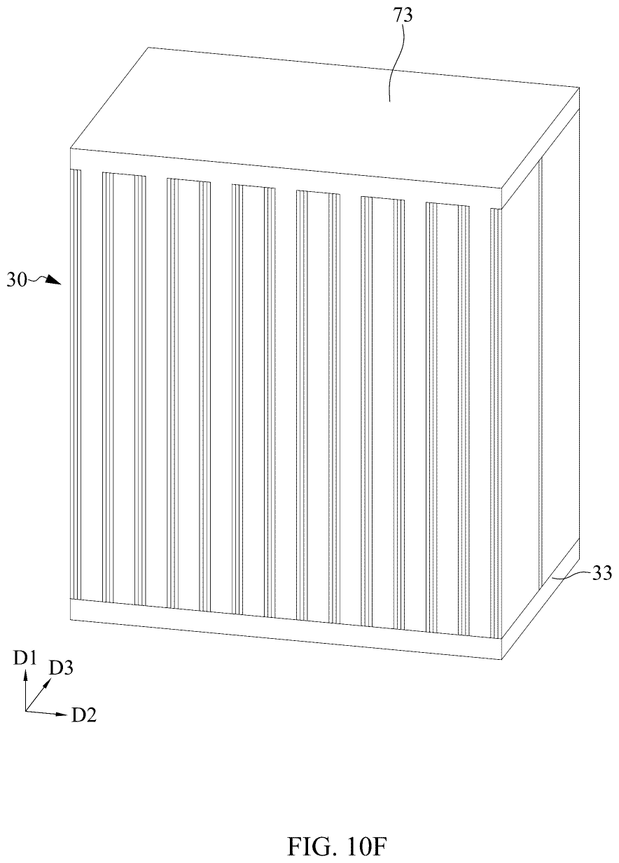

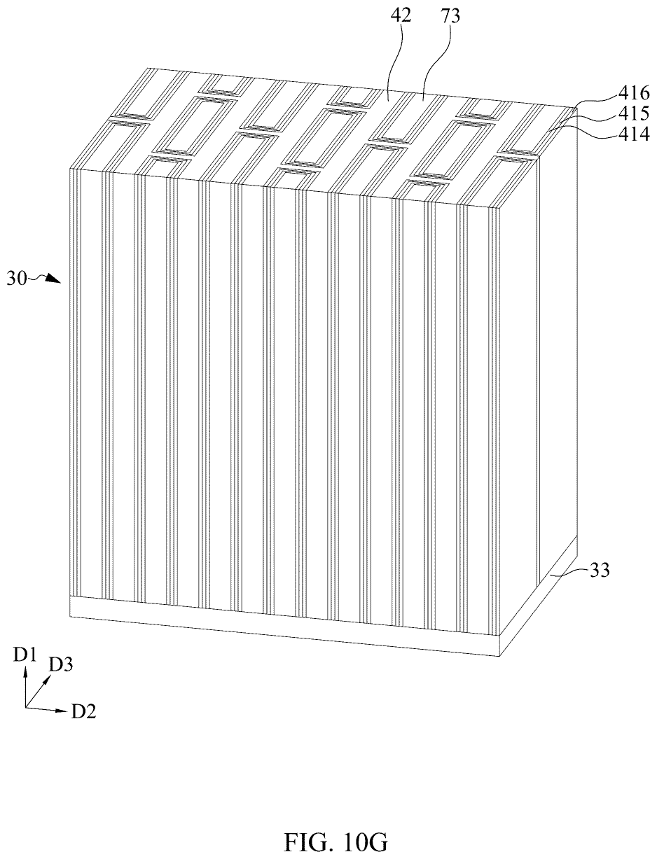

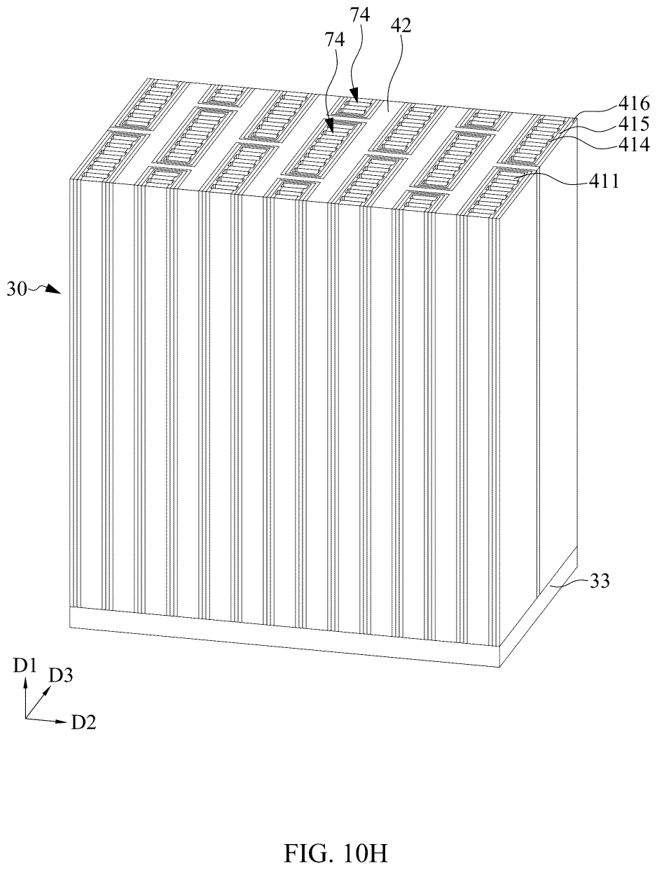

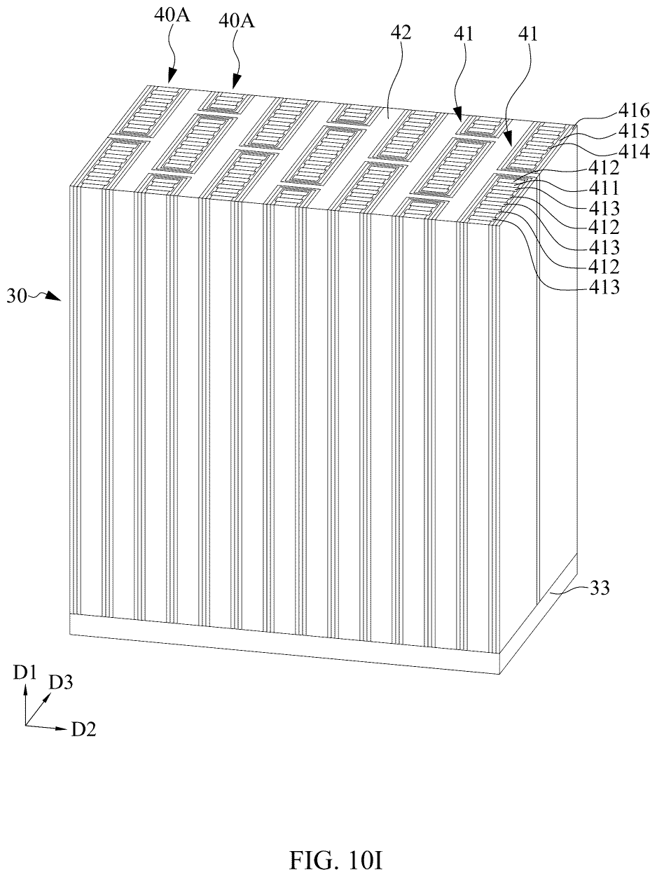

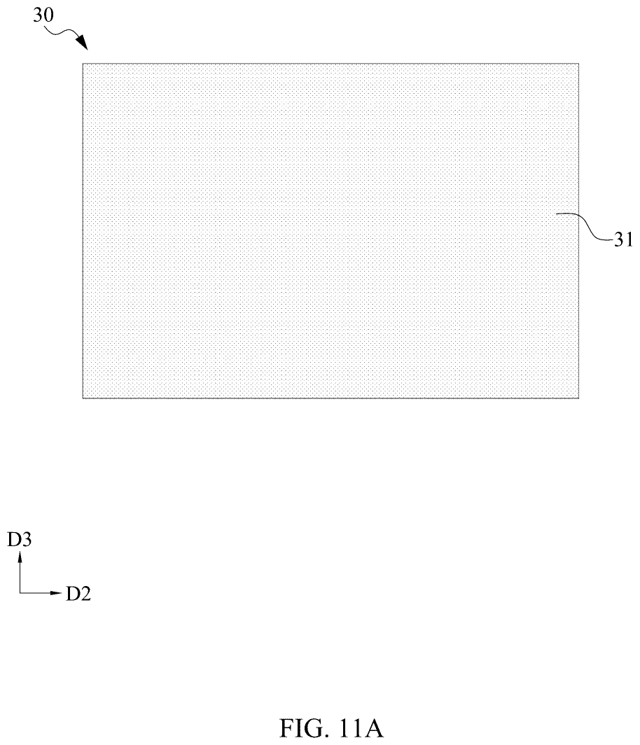

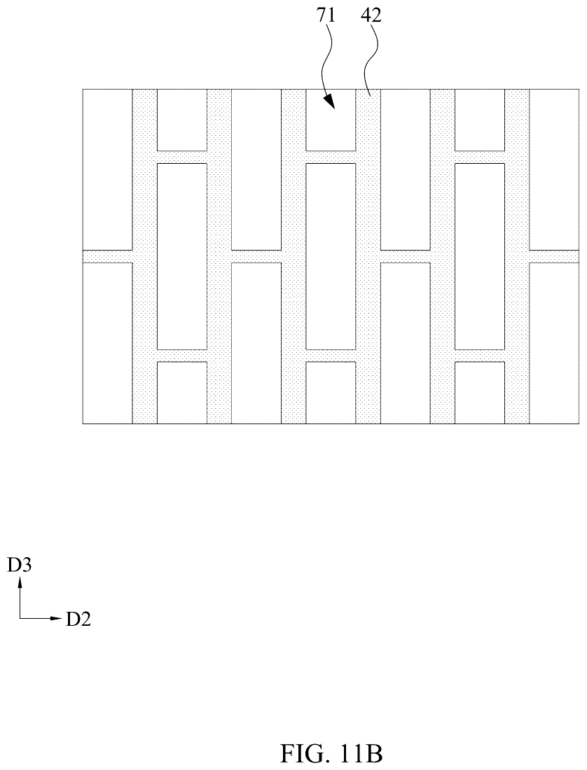

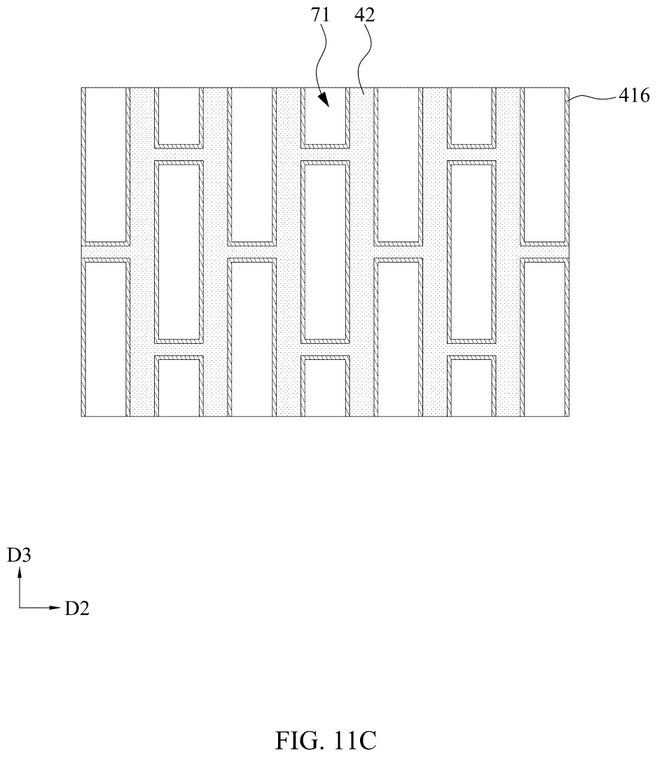

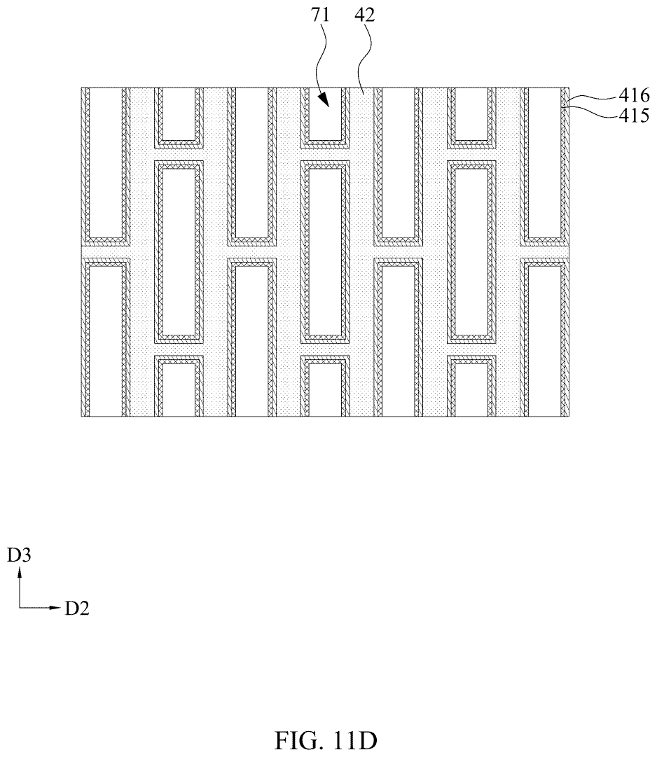

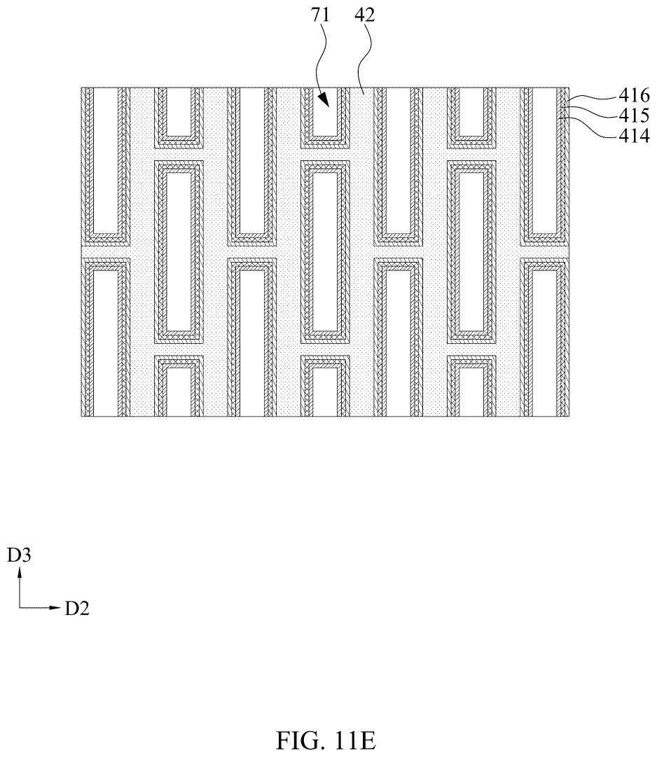

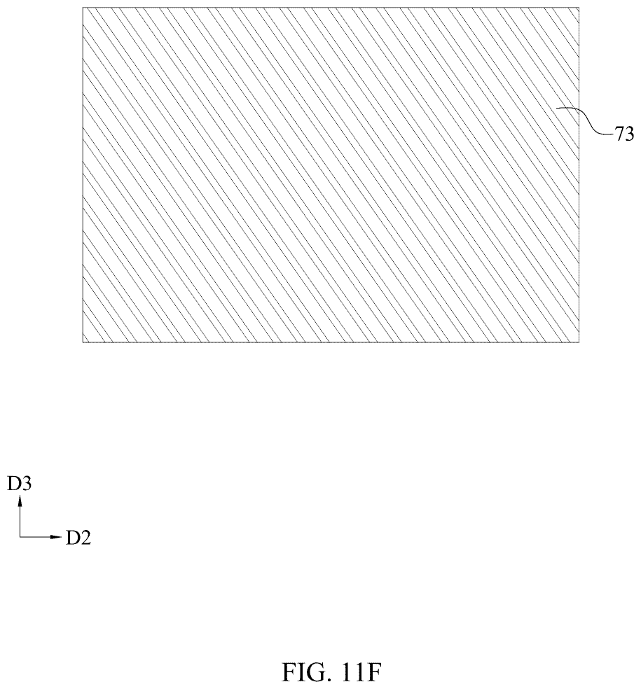

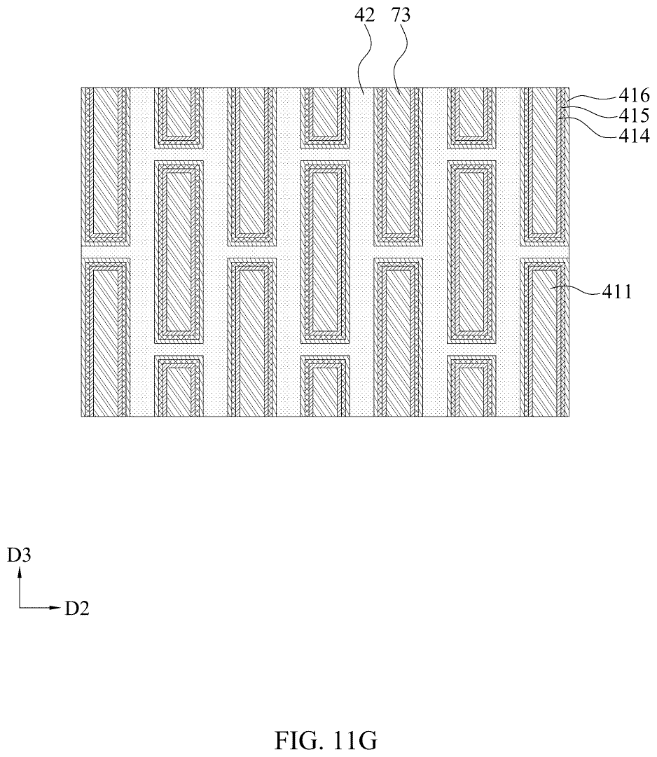

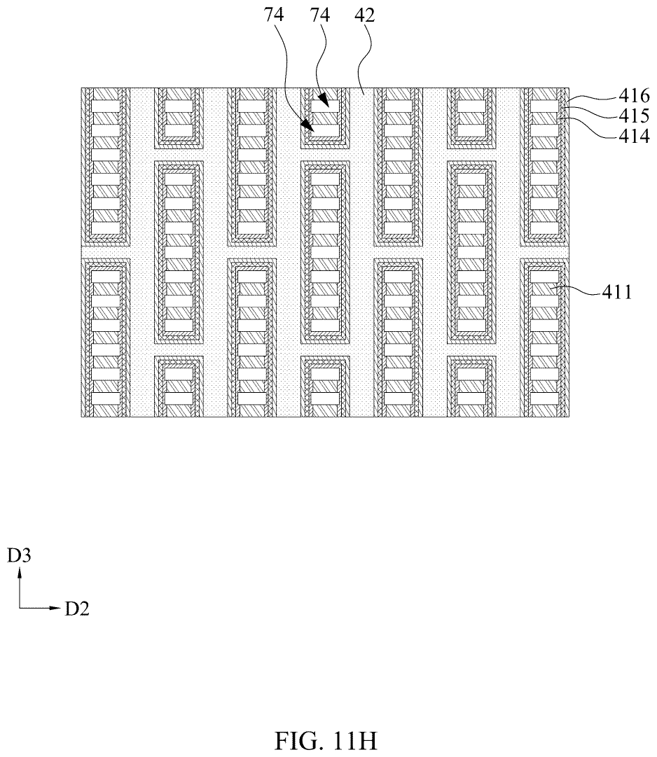

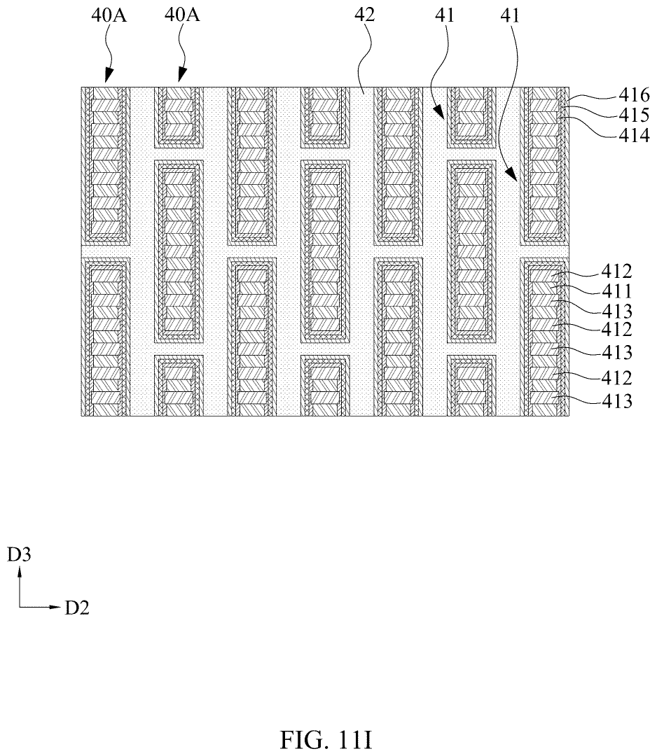

FIG. 7 is a flowchart representing a method 700 for forming a semiconductor structure according to various aspects of the present disclosure. In some embodiments, the method 700 for forming the semiconductor structure includes a number of operations (701, 702, 703, 704, 705 and 706). The method 700 for forming the semiconductor structure will be further described according to one or more embodiments. It should be noted that the operations of the method 700 may be rearranged or otherwise modified within the scope of the various aspects. It should further be noted that additional processes may be provided before, during, and after the method 700, and that some other processes may be only briefly described herein. FIGS. 8A to 8I are diagrammatic perspective views and FIGS. 9A to 9I are corresponding top views illustrating various stages in the method 700 for forming the semiconductor structure according to aspects of one or more embodiments of the present disclosure. FIGS. 10A to 10I are diagrammatic perspective views and FIGS. 11A to 11I are corresponding top views illustrating various stages in the method 700 for forming the semiconductor structure according to aspects of some another embodiments of the present disclosure.

With reference to FIGS. 8A and 9A, the method 700 begins at operation 701 where a substrate with a BEOL interconnect structure 30 is provided and received. The substrate comprises a FEOL structure 10 and a MEOL connecting structure 20 as shown in FIGS. 1 and 2. The BEOL interconnect structure 30 comprises a plurality of metallization layers (M1, M2 . . . Mn). FIGS. 8A and 9A show a dielectric layer 31 in one of the metallization layers (i.e., the Nth metallization layer Mn) overlaid over an underneath layer, which can be a Mn−1 metallization layer. In some embodiments, the dielectric layer 31 in one of the metallization layers may be formed on a conductive pattern 33 or a dielectric layer 31 in the Mn−1 metallization layer.

As shown in FIGS. 8B and 9B, the method 700 continues with operation 702 where a plurality of first trenches 71 are formed in the dielectric layer 31 by etching the dielectric layer 31 along the first direction D1 to expose the underneath layer in the Mn−1 metallization layer so as to define locations of transistor units 41. The plurality of first trenches 71 are arranged in a XY staggered array configuration. The dielectric layer 31 may be an inter-metal dielectric (IMD), a passivation layer or the like. In some embodiments, each of the first trenches 71 has a depth ranging from about 1,000 nm to about 3,000 nm. In some embodiments, the depth of the first trenches 71 may range from about 1,500 nm to about 2,500 nm. In some embodiments, the depth of the first trenches 71 may range from about 1,800 nm to about 2,200 nm. For example, the depth of the first trenches 71 may be about 2,000 nm.

At operation 703, a gate electrode layer 416 is deposited along a sidewall of each first trench 71 as shown in FIGS. 8C and 9C, a gate dielectric layer 415 is deposited along the gate electrode layer 416 as shown in FIGS. 8D and 9D, and a channel layer 414 is deposited along the gate dielectric layer 415 as shown in FIGS. 8E and 9E, so that the first trench 71 remained in the channel layer 414 refers to as a second trench 72. In some embodiments, the gate electrode layer 416 may also deposited on the underneath layer to some extent. In some embodiments, the gate electrode layer 416 can be conformally deposited along the sidewall of each first trench 71 using ALD or other suitable deposition methods and may comprise HfO₂, SiO₂, Al₂O₃, SiON, and so on. In some embodiments, the gate dielectric layer 415 can be conformally deposited along the gate electrode layer 416 using ALD or other suitable deposition methods. In some embodiments, the channel layer 414 can be conformally deposited along the gate dielectric layer 415 using ALD or other suitable deposition methods. The gate electrode layer 416 can be electrically connected to a conductive pattern 33 in a Mn−1 metallization layer.

At operation 704, each second trench 72 is filled with isolation materials 73 as shown in FIGS. 8F and 9F and a planarization (for example, but not limited to, a chemical-mechanical-polishing (CMP)) can be conducted to remove excess isolation materials 73 and to expose a top of the gate electrode layer 416, a top of the gate dielectric layer 415 and a top of the channel layer 414 as shown in FIGS. 8G and 9G.

At operation 705 as illustrated in FIGS. 8H and 9H, the isolation materials 73 filled in each second trench 72 are partially removed to form two third trenches 74 separated by remaining isolation materials 73, which forms a central isolation structure 411. Each of the third trenches 74 is surrounded by the central isolation structure 411 and the channel layer 414. The two third trenches 74 may have the same volume or different volumes. The third trenches 74 are used to define locations of source and drain regions. When forming the third trenches 74 through etching, the channel layer 414 exposed from the third trenches 74 may be etched to some extent and become thinner. The third trench 74 has a width W5, which can be greater than a width W2 of the central isolation structure 411. Therefore, an area of the channel layer 414 adjacent to the central isolation structure 411 is thicker than the areas of the channel layer 414 surrounding the third trenches 74, so that the channel layer 414 has a channel ring 4141 and two extending portions 4142 (i.e., the area of the channel layer 414 adjacent to the central isolation structure 411) as shown in FIG. 4B. In some embodiments, a ratio of the width W5 of the third trench 74 to the width W2 of the central isolation structure 411 may range from about 5:3 to about 50:49. In some embodiments, the ratio of the width W5 of the third trench 74 to the width W2 of the central isolation structure 411 may range from about 10:7 to about 10:9.

At operation 705 as illustrated in FIGS. 8I and 9I, the third trenches 74 beside each central isolation structure 411 are filled with conductive materials so as to form a first conductive region 412 and a second conductive region 413. The first conductive region 412 and the second conductive region 413 may be referred to as source/drain regions. A planarization (for example, but not limited to, CMP) can be conducted, so that a top of the first conductive region 412 and a top of the second conductive region 413 can be substantially coplanar with a top of the gate electrode layer 416, a top of the gate dielectric layer 415 and a top of the channel layer 414. The first conductive region 412 can be electrically connected to a conductive pattern 33 in a Mn+1 metallization layer and the second conductive region 413 can also be electrically connected to a conductive pattern 33 in the Mn+1 metallization layer in the following procedure.

FIGS. 10A to 10I and 11A to 11I illustrate a method 700 for forming a semiconductor structure including a plurality of transistor units 41 with common source/drain regions as shown in FIGS. 5 and 6. Operations 701 to 704 illustrated in FIGS. 10A to 10G and 11A to 11G are similar to those illustrated in FIGS. 8A to 8G and 9A to 9G and thus are omitted in the interest of brevity. At operation 705 as shown in FIGS. 10H and 11H, three or more third trenches 74 may be formed by partially removing the isolation materials 73 in each second trench 72 so as to define locations of source and drain regions. Therefore, two or more central isolation structures 411 can be formed between the three or more third trenches 74.

At operation 706 as shown in FIGS. 10I and 11I, the three or more third trenches 74 are filled with conductive materials to form a plurality of first conductive region 412 and a plurality of the second conductive region 413 alternately, so that the plurality of first conductive region 412 the plurality of the second conductive region 413 are separated from each other by the central isolation structures 411.

By forming vertical transistor regions 40 in the BEOL level, a larger effective area of the channel regions 12 result in an increased electron mobility. Therefore, with about 5% to about 10% reduction of a chip area, the carrier mobility of the BEOL vertical transistor of the present disclosure would not be compromised and may be increased by 5 to 20 times when compared with the carrier mobility of a planar transistor.

In some embodiments, a method for manufacturing a semiconductor structure, comprises providing a substrate with a back-end-of-line (BEOL) interconnect structure; forming a plurality of first trenches in a dielectric layer in the BEOL interconnect structure by etching the dielectric layer along a first direction to define locations of a plurality of transistor units, wherein the plurality of first trenches are arranged in an array along a second direction and a third directions, which are perpendicular to each other and are perpendicular to the first direction; depositing a gate electrode layer along a sidewall of each of the plurality of first trenches; depositing a gate dielectric layer along the gate electrode layer of each of the plurality of first trenches; depositing a channel layer along the gate dielectric layer of each of the plurality of first trenches; filling each of the plurality of first trenches surrounded by the channel layer with isolation materials; forming at least two second trenches by partially removing the isolation materials so that each two of the at least two second trenches are separated from each other by a central isolation structure that is formed by remaining isolation materials, wherein each of the second trenches is surrounded by the channel layer and the central isolation structure; and filling the second trenches with conductive materials to form at least one first conductive region and at least one second conductive region, wherein each of the plurality of transistor units comprises the at least one first conductive region and the at least one second conductive region separated by at least one central isolation structure, the channel layer, the gate dielectric layer and the gate electrode layer.

In some embodiments, a method for manufacturing a semiconductor structure, comprises providing a substrate with a back-end-of-line (BEOL) interconnect structure; forming a first trench in a dielectric layer in the BEOL interconnect structure by etching the dielectric layer along a first direction; depositing a gate electrode layer along a sidewall of the first trench; depositing a gate dielectric layer along the gate electrode layer; depositing a channel layer along the gate dielectric layer; forming a central isolation structure in the first trench; and forming a first conductive region and a second conductive region at opposite sides of the central isolation structure.

In some embodiments, a semiconductor structure comprises a plurality of transistor array regions arranged in parallel along a first direction and each of the plurality of transistor array regions comprising a plurality of transistor units arranged separately along a second direction perpendicular to the first direction, wherein each of the plurality of transistor units comprises: a central portion comprising a first conductive region and a second conductive region separated by a central isolation structure; a channel layer surrounding the central portion; a gate dielectric layer surrounding the channel layer; and a gate electrode layer surrounding the gate dielectric layer; and a separation structure formed between the plurality of transistor units.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for manufacturing a semiconductor structure, comprising:
providing a substrate with a back-end-of-line (BEOL) interconnect structure;
forming a plurality of first trenches in a dielectric layer in the BEOL interconnect structure by etching the dielectric layer along a first direction to define locations of a plurality of transistor units, wherein the plurality of first trenches are arranged in an array along a second direction and a third directions, which are perpendicular to each other and are perpendicular to the first direction;
depositing a gate electrode layer along a sidewall of each of the plurality of first trenches;
depositing a gate dielectric layer along the gate electrode layer of each of the plurality of first trenches;
depositing a channel layer along the gate dielectric layer of each of the plurality of first trenches;
filling each of the plurality of first trenches surrounded by the channel layer with isolation materials;
forming at least two second trenches by partially removing the isolation materials so that each two of the at least two second trenches are separated from each other by a central isolation structure that is formed by remaining isolation materials, wherein each of the second trenches is surrounded by the channel layer and the central isolation structure; and
filling the second trenches with conductive materials to form at least one first conductive region and at least one second conductive region,
wherein each of the plurality of transistor units comprises the at least one first conductive region and the at least one second conductive region separated by at least one central isolation structure, the channel layer, the gate dielectric layer and the gate electrode layer.

2. The method of claim 1, wherein the gate electrode layer is conformally deposited along the sidewall of each of the plurality of first trenches using atomic layer deposition (ALD); the gate dielectric layer is conformally deposited along the gate electrode layer of each of the plurality of first trenches using the ALD; and the channel layer is conformally deposited along the gate dielectric layer of each of the plurality of first trenches using the ALD.

3. The method of claim 1, further comprising conducting a planarization after filling each of the plurality of first trenches surrounded by the channel layer with the isolation materials to expose a top of the gate electrode layer, a top of the gate dielectric layer and a top of the channel layer.

4. The method of claim 1, further comprising conducting a planarization after filling the second trenches with conductive materials, so that a top of the first conductive region and a top of the second conductive region are substantially coplanar with a top of the gate electrode layer, a top of the gate dielectric layer and a top of the channel layer.

5. The method of claim 4, wherein when partially removing the isolation materials surrounded by each channel layer to form the at least two second trenches, the channel layer exposed from the second trenches are etched, so that the channel layer adjacent to the at least one first conductive region and the channel layer adjacent to the at least one second conductive region are thinner than the channel layer adjacent to the at least one central isolation structure.

6. The method of claim 1, wherein the plurality of first trenches are arranged in a staggered array configuration.

7. The method of claim 1, wherein the at least two second trenches have a same volume, so that a volume of the at least one first conductive region is substantially identical to a volume of the at least one second conductive region.

8. A method for manufacturing a semiconductor structure, comprising:
providing a substrate with a back-end-of-line (BEOL) interconnect structure;
forming a first trench in a dielectric layer in the BEOL interconnect structure by etching the dielectric layer along a first direction;
depositing a gate electrode layer along a sidewall of the first trench;
depositing a gate dielectric layer along the gate electrode layer;
depositing a channel layer along the gate dielectric layer;
forming a central isolation structure in the first trench; and
forming a first conductive region and a second conductive region at opposite sides of the central isolation structure.

9. The method of claim 8, wherein the first trench has a rectangular top cross-section and has a height along the first direction and a length along a second direction, and wherein a ratio of the height of the first trench to the length of the first trench ranges from about 50:1 to about 10:1.

10. The method of claim 8, wherein the channel layer comprises a channel ring disposed along the gate electrode layer and separated from the central isolation structure by two extending portions.

11. The method of claim 8, wherein the central isolation structure has a width extending between two sides adjacent to the channel layer, and the first conductive region has a width between two sides adjacent to the channel layer, and wherein a ratio of the width of the central isolation structure to the width of each one of the first conductive region ranges from about 3:5 to about 49:50.

12. The method of claim 8, wherein each of the first trenches has a depth ranging from about 1,000 nm to about 3,000 nm.

13. The method of claim 8, wherein the central isolation structure comprises materials identical to materials of the dielectric layer.

14. The method of claim 8, further comprising:
conducting a first planarization to expose a top of the gate electrode layer, a top of the gate dielectric layer and a top of the channel layer; and
conducting a second planarization so that a top of the first conductive region and a top of the second conductive region are substantially coplanar with a top of the gate electrode layer, a top of the gate dielectric layer and a top of the channel layer.

15. A semiconductor structure, comprising:
a plurality of transistor array regions arranged in parallel along a first direction and each of the plurality of transistor array regions comprising a plurality of transistor units arranged separately along a second direction perpendicular to the first direction, wherein each of the plurality of transistor units comprises:
a central portion comprising a first conductive region and a second conductive region separated by a central isolation structure;
a channel layer surrounding the central portion;
a gate dielectric layer surrounding the channel layer; and
a gate electrode layer surrounding the gate dielectric layer; and
a separation structure formed between the plurality of transistor units.

16. The semiconductor structure of claim 15, wherein a top of the first conductive region and a top of the second conductive region are substantially coplanar with a top of the gate electrode layer, a top of the gate dielectric layer and a top of the channel layer.

17. The semiconductor structure of claim 15, wherein each of the plurality of transistor units has a rectangular top cross-section and has a height along a third direction perpendicular to the first direction and the second direction, and a length along a second direction, and wherein a ratio of the height to the length ranges from about 50:1 to about 10:1.

18. The semiconductor structure of claim 15, wherein the channel layer comprises:
a channel ring disposed along the gate dielectric layer and abutting sidewalls of the first conductive region and the second conductive region; and
two extending portions formed between the channel ring and the central isolation structure.

19. The semiconductor structure of claim 18, wherein the channel ring has a thickness ranging from about 1 nm to about 7 nm; and each of the extending portions has a thickness ranging from about 0.1 nm to about 2.5 nm.

20. The semiconductor structure of claim 15, wherein the plurality of transistor units in one of the plurality of transistor array regions and the plurality of transistor units in an adjacent one of the plurality of transistor array regions are in a staggered array configuration.
